(19) United States
(12) Patent Application Publication
(10) Pub. No.: US 2007/0065180 A1
(43) Pub. Date: Mar. 22, 2007

(54) ORGANIC ELECTROLUMINESCENCE ELEMENT, EXPOSURE DEVICE AND IMAGE FORMING APPARATUS

(75) Inventor: Ryuuichi YATSUNAMI, Fukuoka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/530,652

(22) Filed: Sep. 11, 2006

(30) Foreign Application Priority Data
Sep. 12, 2005 (JP) 2005/263406

(51) Int. Cl. G03G 15/04; H01L 51/52

(52) U.S. Cl. 399/220; 313/506; 428/212; 428/917

(57) ABSTRACT

In applying organic electroluminescence elements as a light source which is required to exhibit the high brightness such as an exposure device, it is necessary to increase light emission efficiency as high as possible to decrease the heat generation and to enhance the reliability of the light source. For this end, the organic electroluminescence element includes a pair of electrodes consisting of an anode and a cathode, and a functional layer having at least light emitting layer and an intermediate layer between the pair of electrodes, and the surface resistivity of the intermediate layer is set to a value equal to or more than 10⁶Ω/□ and equal to or less than 10¹²Ω/□.

### BACKGROUND OF THE INVENTION

1. Field of the Invention

The present invention relates to an organic electroluminescence element which is an electric light emitting element used in various light sources, an exposure device which uses the organic electroluminescence element as a light source, and an image forming apparatus which mounts the exposure device thereon.

2. Description of the Related Art

The organic electroluminescence element is a light emitting device which makes use of an electric-field light emission phenomenon of a solid fluorescent material and has been already partially put into practice as a miniaturized display.

The organic electroluminescence element may be classified into several groups depending on the difference in materials used for forming a light emitting layer. One typical example is a low-molecular organic electroluminescence element which uses an organic compound of a low molecular weight in a light emitting layer thereof and such a low-molecular organic electroluminescence element is manufactured by a vacuum vapor deposition method mainly. Another example is a polymer organic electroluminescence element which uses a polymer compound in a light emitting layer thereof.

In the polymer organic electroluminescence dye, with the use of a solution which dissolves materials for constituting functional layers including at least a light emitting layer in a solvent, it is possible to adopt a film forming step using a spin coating method, an inkjet method, a slit coating method, a dip coating method, a printing method or the like (hereinafter, the film forming step which uses a means to apply a liquid material to form a thin film and exhibits the easy-to-manufacture property which characterizes a manufacturing process of the polymer organic electroluminescence element being referred to as “wet processing”, while a film forming step which is represented by a vacuum vapor deposition method, a sputtering method, a CVD method or the like being referred to as “dry processing”). The wet processing has been attracting attentions as a technique which can realize the reduction of cost and the increase of an area of a screen due to the simplicity of the processing.

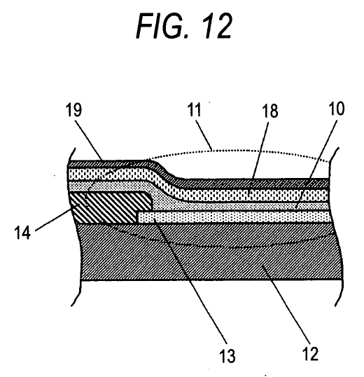

FIG. 12 is a cross-sectional view showing the structure of a conventional polymer organic electroluminescence element.

Hereinafter, the structure of the conventional polymer organic electroluminescence element and steps for manufacturing such an element are explained in conjunction with FIG. 12.

The typical organic electroluminescence element 11 arranges a functional layer between an anode 13 and a cathode 19, wherein the functional layer is formed by stacking a plurality of layers such as a charge injection layer (a PEDOT layer 10 described later) a light emitting layer and the like.

First of all, an ITO (Indium-Tin-Oxide) film is formed as the anode 13 and, thereafter, the anode 13 is formed in a predetermined shape by patterning using etching, and on a glass substrate 12 on which an insulation layer 14 is arranged to obtain a desired light-emitting-surface shape, the PEDOT layer 10 which is made of a PEDOT: PSS (mixture of polythiophene and polystyrene sulfonate, described as PEDOT hereinafter) thin film is formed as the electron injection layer by a spin coating method which constitutes the wet processing or the like. The PEDOT layer 10 is made of the material which constitutes a de facto standard as the carrier injection layer, wherein the PEDOT layer 10 functions as a hole injection layer by being arranged on an anode 13 side.

As the light emitting layer which constitutes the functional layer 18 on the PEDOT layer 10, for example, a film made of, for example, polyphenylene vinylene (hereinafter, expressed as PPV) and a derivative thereof or polyfluorene or a derivative thereof is formed by the spin coating method which constitutes the wet processing or the like. These PPV and poly fluorene are typical materials for forming the light emitting layer used in the polymer organic electroluminescence element 11 and is usually applied in a state that PPV or poly fluorene is dissolved in an organic solvent such as toluene and xylene. Then, a metal electrode which constitutes a cathode 19 is formed on the functional layer 18 as a film by a vacuum vapor deposition method thus completing the organic electroluminescence element 11.

Here, with respect to the conventional organic electroluminescence element, as an attempt to enhance the reliability of the low-molecular organic electroluminescence element particularly, for example, there has been proposed a technique which is disclosed in Japanese Patent Laid-Open 2002-280186, for example, in which intermediate layers which are mainly made of silicon are introduced to the organic electroluminescence element. However, the intermediate layers which are made of such a material possess a large first ionization potential thus generating a remarkable potential gap between the intermediate layers and an electrode. As a result, an electric resistance of the intermediate layers is remarkably increased and hence, it is necessary to decrease a thickness of the intermediate layers as much as possible to enable the injection of electrons at a low voltage. Further, although these intermediate layers have a function of improving the surface roughness of a substrate and preventing the diffusion of impurities to the inside of the functional layer from an electrode surface, the intermediate layers basically function as a barrier layer for electrons and hence, the intermediate layers do not contribute to the enhancement of the light emitting efficiency of the organic electroluminescence element.

While it may be sufficient that the light emitting brightness of the organic electroluminescence element which is applied to a general display device or the like is approximately 1000 cd/m²at maximum, the organic electroluminescence element which is applied to an exposure device of an image forming apparatus such as electro photographic apparatus is required to exhibit the light emitting brightness of 10000/m²or more assuming approximately 600 dpi (dot per inch) and 20 ppm (pages per minute) as the specification of the image forming apparatus, for example, whereby driving conditions of the organic electroluminescence element become extremely severe, that is, a high voltage and a large current. To realize the stable operation of the organic electroluminescence element under such an environment over a long period, it is necessary to largely enhance the light emitting efficiency of the organic electroluminescence element. That is, when the light emitting efficiency of the organic electroluminescence element is high, conditions of a voltage and a current required for driving the organic electroluminescence element are attenuated and hence, the generation of heat by the organic electroluminescence element is decreased thus prolonging a lifetime of the organic electroluminescence element whereby, eventually, it is possible to realize the enhancement of the reliability of the organic electroluminescence element over a long period.

In applying the organic electroluminescence element to the light source such as the exposure device which is required to exhibit the high brightness as described above, it is necessary to increase the light emitting efficiency of the organic electroluminescence element as much as possible to increase the reliability.

### SUMMARY OF THE INVENTION

It is an object of the present invention to provide an organic electroluminescence element which can be driven within a wide range from the low brightness used as a display of a display device to high brightness used as an exposure light source of an image forming apparatus, can be operated in a stable manner within the wide brightness range, and exhibits the excellent lifetime property, an exposure device which is stably operated for a long period by using such an organic electroluminescence element, and an image forming apparatus which exhibits high quality image using the exposure device.

The organic electroluminescence element of the present invention has been made in view of the above-mentioned object and is configured such that the organic electroluminescence element includes a pair of electrodes and a functional layer having at least a light emitting layer and an intermediate layer which are arranged between the pair of electrodes, wherein the surface resistivity of the intermediate layer is set to a value equal to or more than 10⁶Ω/□ and equal to or less than 10¹²Ω/□.

According to the present invention, a light emitting efficiency of the organic electroluminescence element can be enhanced and hence, the organic electroluminescence element can be driven at a lower voltage whereby it is possible to reduce a cost for driving the organic electroluminescence element. Further, it is also possible to suppress an electric crosstalk between neighboring organic electroluminescence elements. Still further, the supply of electricity can be reduced and hence, the heat generation is decreased thus prolonging a lifetime of the organic electroluminescence element.

By applying the organic electroluminescence element to an exposure device, it is possible to provide the exposure device which is operated in a stable manner over a long period. Further, by mounting the exposure device on an image forming apparatus, it is possible to provide an image forming apparatus which can maintain a high image quality over a long period.

To explain typical inventions among inventions described in the specification, they are as follows.

The present invention is directed to the organic electroluminescence element which includes the pair of electrodes and the functional layer having at least the light emitting layer and the intermediate layer which are arranged between the pair of electrodes, wherein the surface resistivity of the intermediate layer is set to a value equal to or more than 10⁶Ω/□ and equal to or less than 10¹²Ω/□. Due to such a constitution, a light emitting efficiency of the organic electroluminescence element can be enhanced and hence, the organic electroluminescence element can be driven at a lower voltage whereby it is possible to reduce a cost for driving the organic electroluminescence element. Further, it is also possible to suppress an electric crosstalk between neighboring organic electroluminescence elements. Still further, the supply of electricity can be reduced and hence, the heat generation is decreased thus prolonging a lifetime of the organic electroluminescence element whereby it is possible to provide the organic electroluminescence element which exhibits high reliability over a long period.

Further, according to the organic electroluminescence element of the present invention, a thickness of the intermediate layer may be set to a value equal to or more than 1 nm and equal to or less than 50 nm. Due to such a constitution, it is possible to suppress an applied voltage at the time of driving the organic electroluminescence element at a low value and hence, a cost for driving the organic electroluminescence element can be decreased and, at the same time, it is possible to substantially ignore the influence of an absorption of light by the intermediate layer even when the intermediate layer exhibits color thus further enhancing the light emitting efficiency of the organic electroluminescence element.

Further, according to the organic electroluminescence element of the present invention, assuming a first ionization potential of the intermediate layer as IP₁eV and a first ionization potential of one of the electrodes as IP₂eV, the intermediate layer may be configured to satisfy the relationship IP₂−0.5 eV≦IP₁≦IP₂+0.5 eV. Due to such a constitution, it is possible to decrease a potential gap between the intermediate layer and the electrode and hence, the applied voltage at the time of driving the organic electroluminescence element can be suppressed at a low value whereby a cost for driving the organic electroluminescence element can be decreased.

Further, according to the organic electroluminescence element of the present invention, the intermediate layer is formed by dry processing. The film forming by dry processing does not generate the non-uniform film thickness attributed to a surface state of a substrate in principle thus obtaining the intermediate layer having a uniform thickness and hence, it is possible to obtain the organic electroluminescence element which exhibits high reliability with uniform light emitting characteristic.

Further, according to the organic electroluminescence element of the present invention, the intermediate layer is made of any one selected from a group consisting of oxide, nitride, oxynitride and composite oxide. These materials are suitable for forming by dry processing such as a vacuum vapor deposition method, a sputtering method, a CVD method and, at the same time, it is possible to form a uniform film on a substrate on which portions which differ from each other in wettability are present in a mixed state and hence, it is possible to realize the electro luminescence element which possesses the uniform light emitting characteristic. Further, oxide, nitride, oxynitride and composite oxide are chemically stable and hence, these materials can suitably protect the glass substrate or the like on which the organic electroluminescence element is formed.

Further, according to the organic electroluminescence element of the present invention, the intermediate layer is made of oxide of transition metal which is any one selected from a group consisting of molybdenum, tungsten and vanadium. Molybdenum oxide, tungsten oxide and vanadium oxide or the like which constitutes the transition metal oxide is sufficiently stable, exhibits the high conductivity which can efficiently perform the carrier injection, and also exhibits the relatively high optical transmissivity. The intermediate layer of the present invention not only simply improves the light emitting efficiency of the organic electroluminescence element but also improves the wettability of the surface on which the functional layer is applied by coating, it is possible to uniformly form the functional layer which is formed on the intermediate layer thus realizing the organic electroluminescence element having the uniform light emitting characteristic.

Further, according to the organic electroluminescence element of the present invention, the functional layer is made of a polymer material by wet processing. Due to such a constitution, the organic electroluminescence element can be formed using the simple wet processing and hence, a cost of a manufacturing facility can be lowered and, at the same time, time necessary for film formation can be shortened thus realizing the reduction of a manufacturing cost of the organic electroluminescence element.

An exposure device of the present invention is configured such that the above-mentioned organic electroluminescence elements are arranged in a row and turning on/off of the individual organic electroluminescence elements are controllable independently from each other. The organic electroluminescence element of the present invention can exhibit the high light emitting efficiency attributed to an advantageous effect which the intermediate layer brings about and hence, a lifetime of the organic electroluminescence element can be prolonged. Further, the intermediate layer is formed to have the uniform thickness by dry processing and hence, a film thickness of a functional layer which is formed on the intermediate layer becomes uniform thus making the distribution of light emitting intensity in a light emitting surface uniform. Accordingly, the exposure device can form a stable latent image over a long period.

An image forming apparatus of the present invention includes the above-mentioned exposure device, a photoconductor on which an electrostatic latent image is formed by the exposure device and a developing means which visualizes the electrostatic latent image which is formed on the photoconductor. Since the exposure device of the present invention can form the stable latent image over the long period, it is possible to maintain a favorable image quality of the image forming apparatus over a long period.

### BRIEF DESCRIPTION OF THE DRAWIGNS

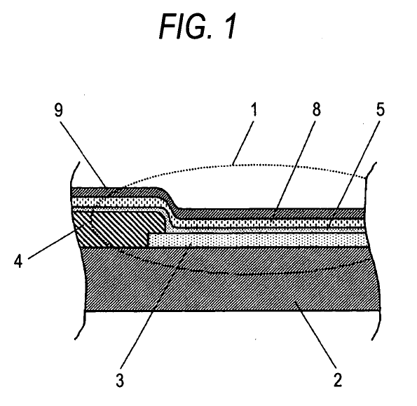

FIG. 1 is a cross-sectional view of an organic electroluminescence element according to an embodiment 1 of the present invention;

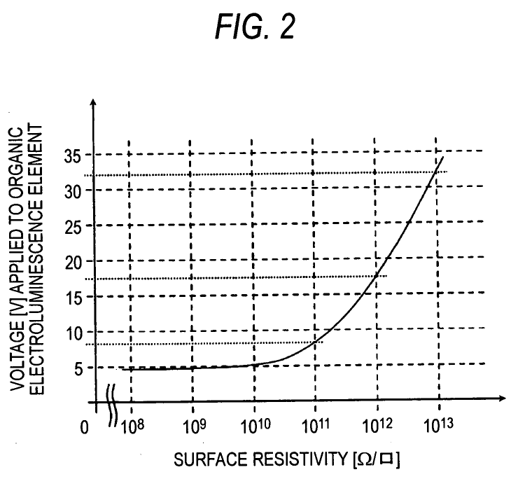

FIG. 2 is a characteristic graph showing the relationship between the surface resistivity of an intermediate layer and a voltage which is applied to the organic electroluminescence element when a thickness of the intermediate layer is set to 30 nm, and the organic electroluminescence element is allowed to radiate light with fixed luminance of 10000 cd/m² in the embodiment 1.

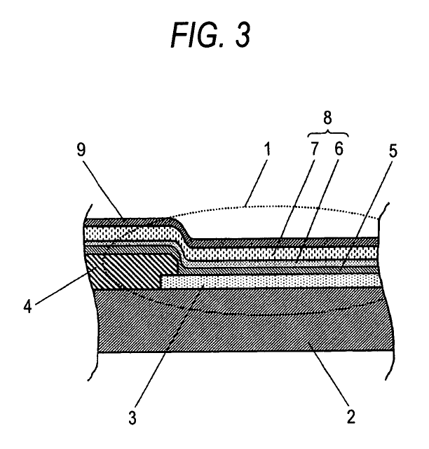

FIG. 3 is a cross-sectional view of an example in which a functional layer is constituted of a plurality of layers in the embodiment 1;

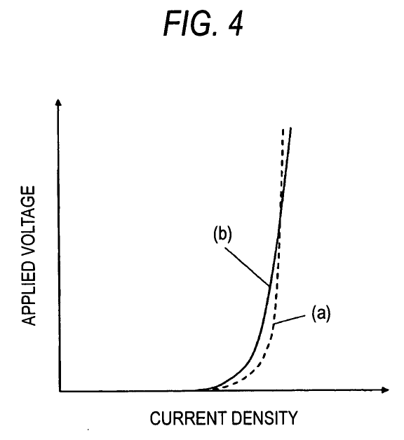

FIG. 4 is a characteristic graph in which the light emission characteristic of the organic electroluminescence element according to the embodiment 1 which has a molybdenum oxide layer as an intermediate layer and the light emission characteristic of an organic electroluminescence element according to a prior art which lacks an intermediate layer are compared with each other;

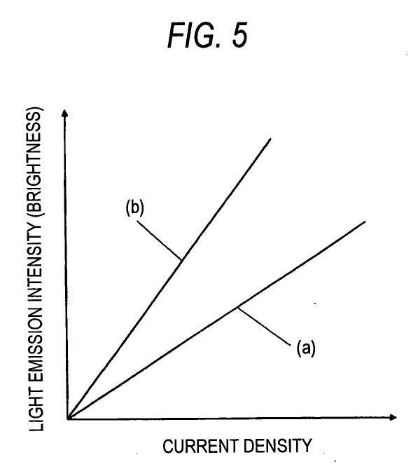

FIG. 5 is a is a characteristic graph in which the light emission characteristic of the organic electroluminescence element according to the embodiment 1 which has the molybdenum oxide layer as the intermediate layer and the light emission characteristic of the organic electroluminescence element according to a prior art which lacks the intermediate layer are compared with each other;

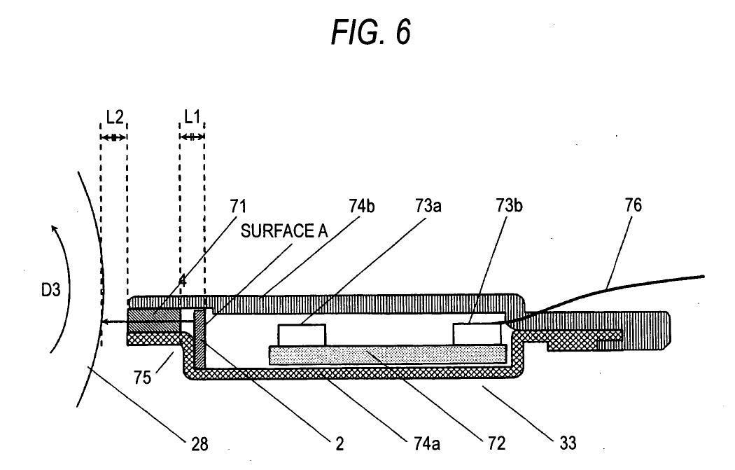

FIG. 6 is a constitutional view of an exposure device according to the embodiment 1;

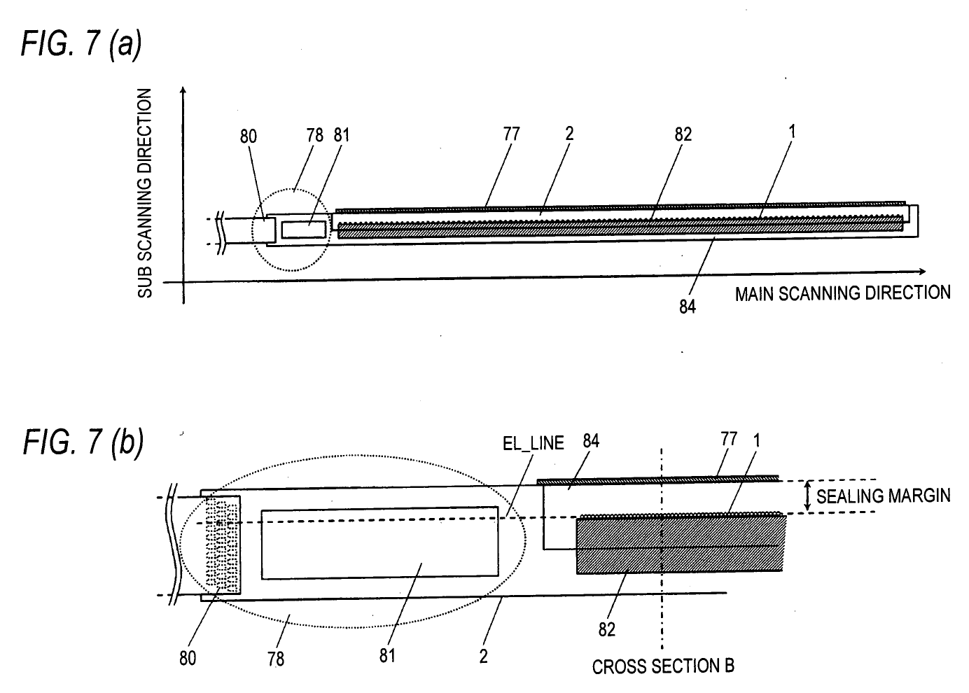

FIG. 7(a) is a top plan view of a glass substrate of an exposure device of the embodiment 1, and FIG. 7(b) is an enlarged view of an essential part of the glass substrate of the exposure device of the embodiment 1;

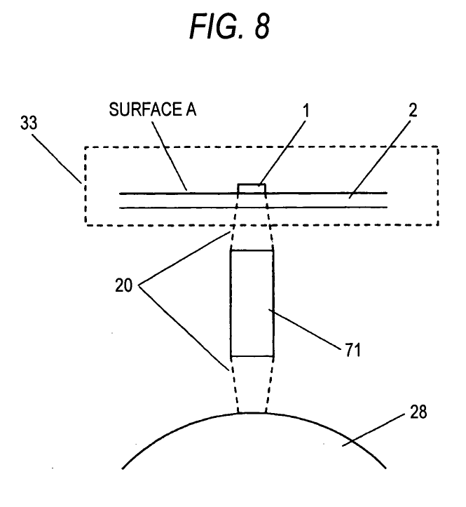

FIG. 8 is an explanatory view showing a situation in which a photoconductor is exposed by the exposure device to which the organic electroluminescence element of the embodiment 1 is applied;

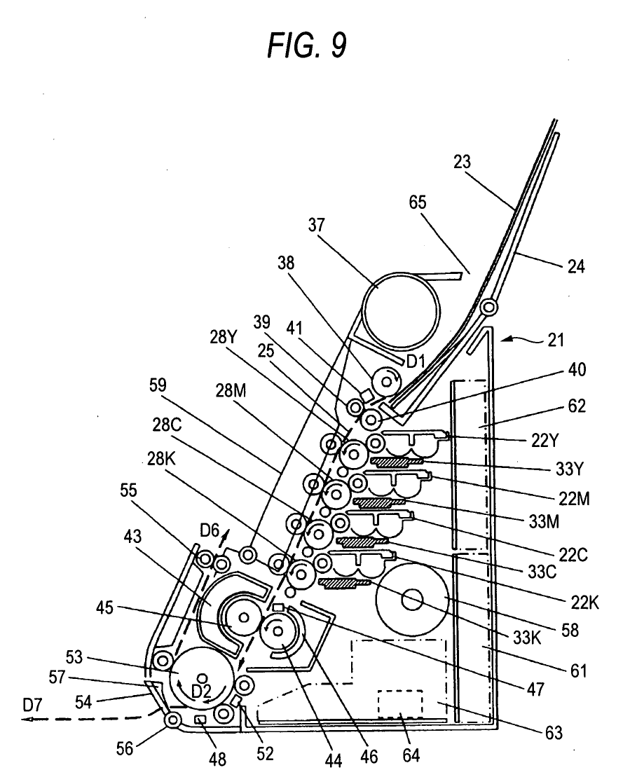

FIG. 9 is a constitutional view of an image forming apparatus on which the exposure device to which the organic electroluminescence element of the embodiment 1 is applied is mounted;

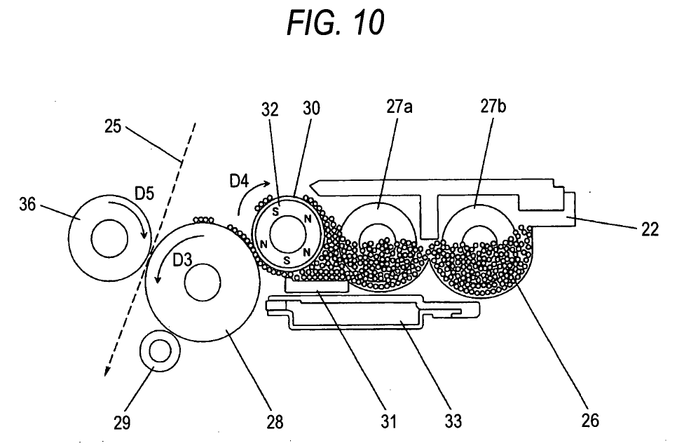

FIG. 10 is a constitutional view showing a periphery of a developing station in an image forming apparatus of the embodiment 1;

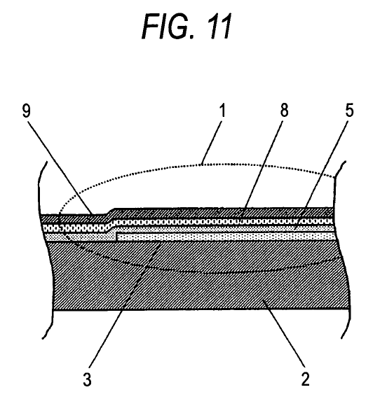

FIG. 11 is a cross-sectional view of an organic electroluminescence element according to an embodiment 2 of the present invention; and

FIG. 12 is a cross-sectional view showing the structure of a conventional polymer organic electroluminescence element.

### DESCRIPTION OF THE PREFERRED EMBODIMENTS

Hereinafter, specific contents of the present invention are explained in conjunction with embodiments.

(Embodiment 1) FIG. 1 is a cross-sectional view of an organic electroluminescence element according to an embodiment 1 of the present invention.

In the explanation made hereinafter, a polymer organic electroluminescence element is simply referred to as “organic electroluminescence element”.

In FIG. 1, numeral 1 indicates an organic electroluminescence element. Numeral 2 indicates, for example, a glass substrate having transmissivity which supports the organic electroluminescence element 1 thereon. Although the detail of steps of manufacturing the organic electroluminescence element 1 is described later, in the embodiment 1, an anode 3 which is made of, for example, ITO or the like having transmissivity is formed on the glass substrate as one of a pair of electrodes, and at least a portion of the anode 3 is covered with an insulating layer 4. On the whole surface of the insulating layer 4, a layer made of molybdenum oxide which is a transition metal oxide is formed as an intermediate layer 5 by dry processing. Next, a functional layer including at least a light emitting layer which is made of a polymer material is formed by wet processing and, finally, a cathode 9 is formed by a vacuum vapor deposition method as another of the pair of electrodes.

In this manner, the organic electroluminescence element 1 of the embodiment 1 is mainly characterized in that the organic electroluminescence element 1 includes a pair of electrodes consisting of the anode 3 and the cathode 9 and the functional layer 8 including at least a light emitting layer and the intermediate layer 5 which are arranged between these electrodes, wherein as described later in detail, a surface resistivity of the intermediate layer 5 is set to a value equal to or more than 10⁶Ω/□ and equal to or less than 10¹²Ω/□.

Using the anode 3 of the organic electroluminescence element 1 as a plus electrode and the cathode 9 of the organic electroluminescence element 1 as a minus electrode, when a DC voltage or a DC current is applied to the organic electroluminescence element 1, holes are injected into the functional layer 8 from the anode 3 via the intermediate layer 5, and electrons are injected into the functional layer 8 a from the cathode 9. In the light emitting layer which is included in the functional layer 8, the holes and the electrons which are injected in this manner are re-coupled and when excitons which are generated by the re-coupling are moved to a ground state from an excited state, a light emitting phenomenon is generated.

Hereinafter, manufacturing steps of the organic electroluminescence element 1 of the embodiment 1 is explained in detail in conjunction with FIG. 1.

Firstly, the steps from the formation of the anode 3 on the glass substrate 2 to the formation of the insulating layer 4 are explained.

An ITO thin film having a thickness approximately 150 to 200 nm is formed on the glass substrate 2 using a sputtering method, and thereafter, by using a photolithographic method and an etching method or the like, an electrode pattern having a predetermined shape is prepared so as to form the anode 3. Subsequently, an insulating material made of photosensitive polyimide is applied to the whole surface of the anode 3 using a spin coating method thus forming an insulating material film having a thickness of approximately 1 μm. Also the photolithographic method is applied for patterning the insulating material film into a predetermined shape to form the insulating layer 4. The insulating layer 4 is patterned so as to cover a boundary portion between the anode 3 and the glass substrate 2 and a shape of the light emitting surface is restricted or defined by the insulating layer 4.

The reason for restricting the shape of the light emitting surface using the insulating layer 4 differs depending on the usage. However, assuming an exposure device as the light emitting device, for example, the restriction of the shape of the light emitting surface is made to accurately determine the position and the shape of the light emitting surface. In the organic electroluminescence element 1, due to the previously-mentioned principle, an overlapped portion of the anode 3 and the cathode 9 which are arranged to face each other emits light and hence, it is possible to directly restrict the position and the shape of the light emitting surface by changing shapes of the anode 3 and the cathode 9. However, in the exposure device, respective light emitting surfaces are extremely small in size and hence, when the restriction is performed only by electrodes such as the anode 3 and the cathode 9, respective electrode lines become too fine and, as a result, there arises a drawback that a resistance value is increased Accordingly, a method in which an electrode having a certain width is prepared so as not to increase the resistance value and a portion thereof is restricted by the insulating layer 4 to restrict the light emitting surface is generally used.

On the glass substrate 2 on which the anode 3 and the insulating layer 4 are formed in the above-mentioned manner, the intermediate layer 5 is formed. Hereinafter, steps for forming the intermediate layer 5 is explained in detail.

In the embodiment 1, as the intermediate layer 5, a layer which has a thickness of 1 to 50 nm and is made of molybdenum trioxide (MoO₃) is formed by a vacuum vapor deposition method which constitutes dry processing. Here, when “molybdenum oxide” is simply referred in the explanation made hereinafter, “molybdenum oxide” implies this molybdenum trioxide (MoO₃), while when the distinction is particularly necessary with respect to the oxidation number of molybdenum, the proper distinction may be described accordingly. The intermediate layer 5 is, as shown in the drawing, configured to be brought into contact with both of the anode 3 and the insulating layer 4. Although the intermediate layer 5 is formed on surfaces of the anode 3 and the insulation layer 4 which differ in wettability from each other, it is possible to form the intermediate layer 5 as a film having a uniform thickness irrelevant to the wettabilities of substrate surfaces due to the characteristic of dry processing. The formation of the intermediate layer 5 as a mask may be performed with respect to the whole surface of the glass substrate 2 or with respect to a portion of the glass substrate 2 using a mask at the time of performing the vacuum vapor deposition.

In this manner, the layer made of molybdenum oxide which is transition metal oxide is formed in contact with the anode 3 and functions as an electron injection (a hole injection) layer.

In any case, to obtain the advantageous effects of the present invention, it is sufficient that at least the anode 3 is covered with the molybdenum oxide layer. However, in case of the organic electroluminescence element 1 which forms the light emitting region by restricting the anode 3 with the insulation layer 4 as described above, from a viewpoint of making surfaces of the structural body having different wettabilities uniform, it is preferable to cover a boundary portion between the anode 3 and the insulation layer 4 or the whole surface including the anode 3 and the insulation layer 4 with the molybdenum oxide layer.

Here, the molybdenum oxide layer made of transition metal oxide which constitutes the intermediate layer 5 is formed by filling molybdenum oxide powder in a vapor deposition boat (BU-6: Japan Vacs Metal Co., Ltd) which is made of molybdenum and the vapor deposition is performed using a vacuum vapor deposition device of a resistance heating type at a vapor deposition rate which falls within a range from substantially 0.1 nm/second to 10 nm/second. According to an actual measurement carried out by inventers of the present invention, the surface resistivity falls within a range from 10¹⁰Ω/□ to 10¹¹Ω/□. The surface resistivity can be measured using an equipment such as R8340 of an Advantest Corporation, for example.

In this manner, the embodiment 1 uses the vacuum vapor deposition method informing the intermediate layer 5. However, it is needless to say that the film forming method is not limited to the vacuum vapor deposition method and it is possible to obtain an oxide molybdenum film having the above-mentioned property using a general dry film forming device such as a sputtering method or an electron beam vapor deposition device.

As mentioned previously, molybdenum oxide which is referred in the present invention is mainly composed of molybdenum trioxide. However, for example, by substituting a portion of molybdenum trioxide with molybdenum dioxide or other composition (the composition in which depletion of oxygen or other impurities are mixed) thus forming a film in which both compositions are present in mixture, it is possible to easily control the surface resistivity of the intermediate layer 5 to assume a value which falls within a range from 10⁶Ω/□ to 10¹²Ω/□. The surface resistivity is increased along with the increase of a ratio of molybdenum trioxide, while the surface resistivity is decreased due to the presence of the depletion of oxygen such as molybdenum dioxide.

The molybdenum trioxide single body is fundamentally an insulating body and the surface resistivity of a pure molybdenum trioxide film largely exceeds 10¹²Ω/□. On the other hand, molybdenum dioxide possesses the low resistivity (8.8×10⁻⁶Ωcm) which is substantially equal to the resistivity of a kind of metal. By forming the film in which molybdenum trioxide and molybdenum dioxide are present at a desired mixing ratio, it is possible to control the surface resistivity of the intermediate layer 5. Here, in forming the film in which molybdenum trioxide and molybdenum dioxide are present in mixture, several methods are considered including a method which forms the film by controlling atmosphere using a sputtering method or a method which performs co-vapor deposition using an electron beam vapor deposition method, wherein these methods can be easily performed. In using the vapor deposition method, a resistance value can be changed by controlling a vapor deposition rate or purities of raw materials, while in using the sputtering method, a resistance value can be changed by controlling sputtering atmosphere (a rate among nitrogen, argon and oxygen or the like)

Further, titanium nitride, zirconium nitride or the like also has the resistivity at the same level as molybdenum dioxide. By forming the film by substituting molybdenum dioxide with these materials or by combining molybdenum dioxide with other material having the further higher resistance, it is also possible to form the intermediate layer 5 having the surface resistivity which falls within a range from 10⁶Ω/□ to 10¹²Ω/□.

Hereinafter, a ground for setting the surface resistivity of the intermediate layer to the value which falls within the range from 10⁶Ω/□ to 10¹²Ω/□ in the organic electroluminescence element 1 of the embodiment 1 is explained in detail.

When the surface resistivity of the intermediate layer 5 is increased and the characteristic of molybdenum oxide as the insulator becomes dominant, the insulating property of the intermediate layer 5 per se is increased and hence, the electric resistance of the organic electroluminescence element 1 as a whole is increased. Since it is possible to effectively inject holes in the intermediate layer 5 which is formed of the molybdenum oxide layer, even when the light emitting efficiency for a drive current is increased, a voltage necessary for driving the organic electroluminescence element 1 is increased thus leading to the increase of a cost of a driver or the like which becomes necessary for driving the organic electroluminescence element 1. With respect to this driver, it is considered that when a CMOS process rule of 0.5 μm is used in general, a cost is pushed up by approximately 1.3 times when the driver exceeds 20 V dielectric strength. Further, with the elevation of a power source voltage which drives the organic electroluminescence element 1, a power source cost is also pushed up and hence, it is not preferable to easily allow the elevation of the drive voltage.

FIG. 2 is a characteristic graph showing the relationship between the surface resistivity of an intermediate layer 5 and a voltage which is applied to the organic electroluminescence element 1 when a thickness of the intermediate layer 5 is set to 30 nm, and the organic electroluminescence element 1 is allowed to radiate light with fixed luminance of 10000 cd/m² in the embodiment 1 of the present invention.

Hereinafter, a setting range of the surface resistivity in the embodiment 1 is explained in conjunction with FIG. 2 together with FIG. 1.

From FIG. 2, it is understood that a voltage which is applied to the organic electroluminescence element 1 is not so large, that is, approximately 5 V within the range in which the surface resistivity of the intermediate layer 5 does not exceed 10¹¹Ω/□, and is sharply increased when surface resistivity exceeds 10¹¹Ω/□. This implies that, when the surface resistivity of the intermediate layer 5 is in the vicinity of or below 10¹⁰Ω/□, the resistance of the portion other than the intermediate layer 5 such as the functional layer 8 becomes relatively larger than the resistance of the intermediate layer 5 and hence, the applied voltage is controlled by the resistances of portions other than the intermediate layer 5. Further, this also implies that when the surface resistivity of the intermediate layer 5 exceeds 10¹⁰Ω/□, the resistance of the intermediate layer 5 controls the resistance of the whole organic electroluminescence element 1 and hence, the voltage which is applied to the organic electroluminescence element 1 is sharply elevated.

According to the graph shown in FIG. 2, the applied voltage to the organic electroluminescence element 1 is approximately 17V to 18V when the surface resistivity is 10¹²Ω/□ and hence, it is possible to use the driver which is constituted of CMOS and can be manufactured at a low cost. However, when the surface resistivity is 10¹³Ω/□, the surface resistivity is elevated to approximately 32V and hence, a manufacturing cost is increased whereby the use of the intermediate layer 5 having the resistivity of approximately 32V is not desirable.

In view of the above-mentioned observation, it is desirable that the surface resistivity of the intermediate layer 5 does not exceed 10¹²Ω/□.

On the other hand, when the organic electroluminescence element 1 is driven using the thin film transistor (TFT) (that is, when the active matrix driving is performed), the dielectric strength (maximum rated voltage) of the TFT is generally designed to approximately 1.2 V, the surface resistivity of the intermediate layer 5 may be set to a value equal to or less than 10¹¹Ω/□. It is needless to say that the dielectric strength of the TFT is determined based on the insulating performance between a channel region and a gate electrode which are made of poly-silicon, for example, and hence, the dielectric strength of the TFT is enhanced by increasing a thickness of the insulating layer, for example. In this case, however, a tact time at the time of manufacturing the organic electroluminescence element 1 is increased and hence, it is disadvantageous in terms of cost. Here, the circumstance is not largely changed with respect to the situation in which the TFT made of an organic material, that is, the so-called organic TFT is used and hence, the surface resistivity of the intermediate layer 5 may be set to a value equal to or less than 10¹¹Ω/□.

On the other hand, when the insulating property of the intermediate layer 5 per se is lowered and the electric resistance of the intermediate layer 5 per se is lowered, an unintentional circuit is formed between the neighboring organic electroluminescence elements 1 by way of the intermediate layer 5 thus giving rise to the generation of a so-called leaked current.

Table 1 shows a calculated ratio between a resistance value in the film thickness direction of the organic electroluminescence element 1 and a resistance value between neighboring organic electroluminescence elements (hereinafter simply referred to as “between the neighboring elements”).

TABLE 1

| Intermediate | | | | | | | |
|---|---|---|---|---|---|---|---|
| layer | | | | | | | |
| thickness | Surface resistance ratio [Ω/□] | | | | | | |
| [μm] | 1.00E+11 | 1.00E+10 | 1.00E+9 | 1.00E+8 | 1.00E+7 | 1.00E+6 | 1.00E+5 |
| 0.001 | 806000000 | 80600000 | 8060000 | 806000 | 80600 | 8060 | 806 |
| 0.002 | 201500000 | 20150000 | 2015000 | 201500 | 20150 | 2015 | 202 |
| 0.005 | 32240000 | 3224000 | 322400 | 32240 | 3224 | 322 | 32 |
| 0.01 | 8060000 | 806000 | 80600 | 8060 | 806 | 81 | 8 |
| 0.02 | 2015000 | 201500 | 20150 | 2015 | 202 | 20 | 2 |
| 0.03 | 895556 | 89556 | 8956 | 896 | 90 | 9 | 1 |
| 0.04 | 503750 | 50375 | 5038 | 504 | 50 | 5 | 1 |
| 0.05 | 322400 | 32240 | 3224 | 322 | 32 | 3 | 0 |
| 0.06 | 223889 | 22389 | 2239 | 224 | 22 | 2 | 0 |

In the exposure device of the embodiment 1, as explained later in detail, a large number of organic electroluminescence element 1 are arranged in a close contact manner. Assuming the resolution which is used in general in a printer as 600 dpi (dot per inch), an arrangement pitch of the organic electroluminescence element 1 which constitutes the exposure light source becomes 42.3 μm.

The respective numerical values in Table are obtained by calculating a ratio between the resistance value in the film thickness direction and the resistance value between the neighboring elements based on a following formula by setting a size of one side of the organic electroluminescence element 1 as M=40.3 μm, a distance S between the neighboring organic electroluminescence elements 1 which is a value obtained by subtracting the above-mentioned size M from an arrangement pitch of 42.3 μm, and a resistance value R2 of the functional layer 8 in the film thickness direction as R2=10¹⁰Ω/□, and by using the surface resistivity R1Ω/□ of the intermediate layer 5 and a thickness Lμm of the intermediate layer 5 as parameters.
{(M×M)/(L×R2)}/{(M×L)/(S×R1)}={(40.3×40.3)/(L×10¹⁰)}/{(40.3×L)/(2×R1)}

Hereinafter, examples which are provided to cope with a leaked current are explained in conjunction with Table 1.

First of all, as one example, a case in which a thickness of the intermediate layer 5 is set as 10 nm (see a row of 0.01 μm of “thickness of intermediate layer”in Table 1). Here, it is understood that when the surface resistivity of the intermediate layer 5 is 10¹⁰Ω/□ or more, a ratio between the resistance value of the organic electroluminescence element 1 in the film thickness direction and the resistance value between the neighboring pixels exceeds 800,000.

This implies that only 1/800,000 of a current which flows in the organic electroluminescence element 1 to make the organic electroluminescence element 1 to emit light flows in the neighboring pixel and this value may be ignored in the actual operation. However, when the surface resistivity of the intermediate layer 5 is 10⁶Ω/□, the resistance value of the organic electroluminescence element 1 in the film thickness direction is controlled by portions other than the intermediate layer 5 and hence, the resistance is not changed considerably, while the resistance value between the neighboring pixels is lowered corresponding to the lowering of the resistance value of the intermediate layer 5 whereby the resistance ratio becomes approximately 80 eventually (see the numerical value of the surface resistivity=1.00E+06 of the row having “intermediate layer thickness” of 0.01 μm in Table 1). This implies that 1/80 of the current for making the organic electroluminescence element 1 emits light flows in the neighboring pixel. Since a linear relationship is established between the current value and the light emission brightness in the general organic electroluminescence element 1, the 1/80 leaked current implies that the neighboring pixel emits light with the 1/80 light emitting intensity.

In general, in a display device such as a display, for example, in view of the necessity to display a gray scale image of multiple values, the image data requires 6 bits, that is, 64 or more steps and hence, the 1/80 leaked current is equal to or less than this step width and hence, the leaked current is considered to be within an allowable range. Accordingly, the surface resistivity of the intermediate layer 5 should be set to a value which does not become lower than 10⁶Ω/□ at minimum.

Further, when the organic electroluminescence element 1 is applied to the exposure device, in the embodiment 1, as explained later, in an image forming apparatus on which the exposure device is mounted, the light quantity correction is performed with respect to the deterioration of the organic electroluminescence element 1 along a lapse of time. The accuracy of this light quantity correction is stricter than the light quantity correction of the above-mentioned display device, that is, 8 bits, that is, 256 steps. The above-mentioned 1/80 leaked current is 3 times as large as 1 step of the light quantity correction or more and hence, when such an excessive leaked current is generated, it is substantially difficult to perform the light quantity correction. To make use of at least the light quantity correction accuracy of 8 bits, it is necessary to set the ratio between the resistance value of the organic electroluminescence element 1 in the film thickness direction and the resistance value between the neighboring pixels to 256 or more, and it is desirable to set the ratio to 512 or more to ignore the influence to the accuracy of light quantity correction.

According to Table 1, even when the thickness of the intermediate layer 5 is extremely small, that is, 1 nm (=0.001 μm) as a range which satisfies this condition, so long as the surface resistivity of 10⁵Ω/□ is ensured, the resistance ratio is 806 and hence, the accuracy of light quantity correction can be logically ensured. However, to further emphasize a manufacturing yield rate of the organic electroluminescence element 1, it is desirable to set a thickness of the intermediate layer 5 to 5 nm (=0.005 μm) or more. To take the above into consideration, it is necessary to ensure 10⁶Ω/□ (the numerical value in Table 1 being 322) or more as the surface resistivity.

As described above, there exists the allowable range with respect to the surface resistivity of the intermediate layer 5, and the range is a range from 10⁶Ω/□ to 10¹²Ω/□.

Further, in assigning priority to the manufacturing yield rate of the organic electroluminescence element 1, there may be a case that the thickness of the intermediate layer 5 is set to a larger value which is inferior from a viewpoint of the leaked current. This may be a case in which a value which falls within a range from 20 nm to 50 nm is selected as the thickness of the intermediate layer 5. According to Table 1, within such a range, there exists a more desirable range, that is, a range in which the surface resistivity assumes a value equal to or more than 10⁸Ω/□. So long as the surface resistivity assumes the value equal to or more than 10⁸Ω/□ with the thickness of the intermediate layer 5 which falls within the range of 20 nm to 30 nm, all of ratios between the resistance values of the organic electroluminescence element 1 in the film thickness direction and the resistance values between the neighboring pixels exceed 256 and hence, it is possible to perform the light quantity correction with high accuracy by eliminating an electrical crosstalk.

To summarize the above, it is preferable to set the surface resistivity (Ri) of the intermediate layer 5 to values which fall within following ranges respectively depending on applications in which the organic electroluminescence element 1 is used.

i) Application such as a display in which a small amount of defects in the organic electroluminescence element 1 is allowable: 10⁶Ω/□≦Ri≦10¹²Ω/□

ii) Application such as an exposure device in which the presence of defects in the organic electroluminescence element 1 is not allowable (that is, an utmost priority being assigned to a yield rate): 10⁸Ω/□≦Ri≦10¹²Ω/□

iii) The above-mentioned application ii) in which the organic electroluminescence element 1 is further driven by a TFT: 10⁶Ω/□≦Ri≦10¹¹Ω/□

iv) The above-mentioned application ii) in which the organic electroluminescence element 1 is further driven by a TFT: 10⁸Ω/□≦Ri≦10¹¹Ω/□

Further, assuming a first ionization potential of the intermediate layer 5 as IP₁eV and a first ionization potential of the anode 3 which constitutes one electrode out of the pair of electrodes as IP₂eV, the organic electroluminescence element 1 is configured such that the intermediate layer 5 satisfies the relationship IP₂−0.5 eV≦IP₁≦IP₂+0.5 eV.

The value of the first ionization potential is a value intrinsic to a material which is not originally influenced by film forming conditions or the like. However, in the actually manufacturing film and actually measuring the first ionization potential, the first ionization potential assumes a value which falls within a certain range. It is considered that this is attributed to a fact that the first ionization potential is changed due to the arrangement of a material which is formed into a film, that is, whether the material is crystalline or amorphous, the presence of impurities or the difference in a joining state when the film is made of a compound such as oxide.

Particularly, when the oxide film is formed by vacuum vapor deposition as in the case of the embodiment 1, it may be considered that by heating the oxide in the reducing atmosphere such as a vacuum state, a portion of the compound is changed to a reducing material, that is, the compound is changed into a state in which the number of oxidation is set to a smaller value. In general, oxide exhibits a tendency that the larger the number of oxidation, the first ionization potential is increased. That is, trioxide exhibits the larger first ionization potential than dioxide. Accordingly, when oxide is heated more strongly, that is, the vapor deposition is performed with a higher vapor deposition rate in performing the vacuum vapor deposition using the resistance heating, for example, there exists a tendency that the decomposition toward a reduction side is generated and the first ionization potential is decreased. Further, to the contrary, when oxygen is introduced into a reactor vessel in sputtering or the like thus forming a film in the oxidation atmosphere (it is needless to say that the material to be formed into the film can be further oxidized), a portion of the film assumes a state in which the number of oxidation is increased thus realizing a state in which the first ionization potential is increased as a whole.

That is, to realize the relationship between the first ionization potentials of the anode 3 and the intermediate layer 5, although it is necessary to select the proper combination of the material groups basically, it is possible to control the relationship depending on the film forming condition as described above when the first ionization potential falls within a range of approximately ±0.5 eV.

Several methods are considered for measuring the first ionization potential and the measurement result differs within a range of slight irregularities depending on the measuring methods. With respect to the organic electroluminescence element 1 based on the embodiment 1, the first ionization potential is measured using a surface analyzer AC-1 (made by Riken Keiki Co., Ltd).

The difference between the first ionization potential of the anode 3 made of ITO and the first ionization potential of the intermediate layer 5 generates an ohmic joint and a Shotockey joint depending on the magnitude relationship between these first ionization potentials. In allowing electrons to pass on a joining surface, when the ohmic joint is made between the anode 3 and the intermediate layer 5, the electrons pass without problems, while when the Shottky joint is made between the anode 3 and the intermediate layer 5, the joining surface becomes a barrier for electrons. Such an electric state on the joint surface is a basic matter in a general semiconductor theory and hence, the detailed explanation of the electric state is omitted here. However, it must be noted that a height of the barrier corresponds to the difference between the first ionization potentials of materials which constitute the joint surface. That is, to get over the high barrier, the higher energy becomes necessary. This implies that it is necessary to apply a high voltage to the organic electroluminescence element 1.

In this manner, the difference between the first ionization potentials of the anode 3 and the intermediate layer 5 forms a potential gap and induces the increase of the applied voltage and hence, it is desirable to perform the selection of materials to prevent the potential gap from becoming increased excessively. The first ionization potential of the anode 3 in general which is made of ITO assumes a value in the vicinity of 5 eV, while to take the potential gap into consideration, it is desirable that the first ionization potential of the intermediate layer 5 does not assume a value which exceeds 5.5 eV. The first ionization potential formed of a molybdenum oxide layer which is actually adopted by the embodiment 1 is 5.5 eV according to the above-mentioned measuring equipment. According to the above-mentioned concept, even when the difference between the first ionization potentials is large, it may be sufficient to apply the voltage corresponding to the difference between the first ionization potentials. However, as explained previously, the organic electroluminescence element 1 of the embodiment 1 is formed of the extremely thin film and, at the same time, the constitutional material of the organic electroluminescence element 1 is an organic material which is fundamentally not a good electron conductive body. Accordingly, when the excessively high voltage is applied to the organic electroluminescence element 1, an interlayer insulation breakdown may occur prior to the original operation of the organic electroluminescence element 1, that is, the emission of light.

Further, in the embodiment 1, the thickness of the intermediate layer 5 is set to a value equal to or more than 1 nm and equal to or less than 50 nm. The reason for setting the thickness of the intermediate layer 5 to such a value is explained in detail hereinafter.

The molybdenum oxide layer which constitutes the intermediate layer 5 in the organic electroluminescence element 1 of the embodiment 1 exhibits slightly gray color. Accordingly, when the intermediate layer 5 has the excessively large thickness, a portion of the emitted light is absorbed and light which is taken out to the outside is decreased and hence, the substantial light emitting efficiency is lowered. Accordingly, it is desirable that the intermediate layer 5 is made as thin as possible. However, when the film thickness of the intermediate layer 5 is made extremely small, a film having a uniform thickness cannot be formed and hence, the intermediate layer 5 cannot obtain the original advantages thereof eventually. To prevent the insulation breakdown of the organic electroluminescence element 1 and to allow the intermediate layer 5 to obtain the film thickness which enables the uniform covering of the surface of the anode 3 with the intermediate layer 5, it is desirable to set the film thickness of the intermediate layer 5 to 1 nm or more at minimum. Further, when the film thickness of the intermediate layer 5 is excessively increased, the undesired light absorption is increased and, at the same time, a voltage applied to the organic electroluminescence element 1 is increased.

Here, the explanation will be made by taking the organic electroluminescence element 1 which forms the molybdenum oxide layer having the surface resistivity in the vicinity of 10¹¹Ω/□ as an example in conjunction with also FIG. 2 besides FIG. 1. In FIG. 2, in driving the organic electroluminescence element 1 with a constant brightness of 10000 cd/m², an applied voltage which the organic electroluminescence element 1 which is provided with the molybdenum oxide layer having the surface resistivity in the vicinity of 10¹¹Ω/□ as the intermediate layer 5 requires is 8V to 9V. This applied voltage is applicable to a case in which the molybdenum oxide layer has the film thickness of 30 nm. When the film thickness of the molybdenum oxide layer is increased to 50 nm for enhancing the manufacturing yield rate as mentioned previously, although the surface resistivity is lowered along with the increase of the film thickness (see Table 1), the resistance in the thickness direction of the organic electroluminescence element 1 is increased depending on the film thickness and it is expected such that the applied voltage is increased to approximately 12V. Further, this explanation is applicable to a case in which the surface resistivity of the molybdenum oxide layer assumes a value in the vicinity of 10¹¹Ω/□ and the elevation of the voltage becomes more apparent as the surface resistivity approaches 10¹²Ω/□ and there exists a possibility that the applied voltage becomes approximately 20V.

Such elevation of the applied voltage brings about the increase of a cost of the driver or the like necessary for driving the organic electroluminescence element 1 as mentioned previously. Accordingly, it is preferable to maintain the film thickness of the intermediate layer 5 to a fixed value or less and should be maintained at a value equal to or less than 50 nm at maximum in view of the above-mentioned observation.

Although the intermediate layer 5 is formed using the vacuum vapor deposition method in the embodiment 1, it is needless to say that the intermediate layer 5 may be formed using other drying process such as the sputtering method. For example, the molybdenum oxide and vanadium oxide have sublimity and hence, the film formation using these materials by the general vacuum vapor deposition is possible. However, when tungsten oxide is used as the material for forming the intermediate layer 5, it is necessary to form the film by sputtering. Further, among the above-mentioned other oxides, there are many materials which are not suitable for vacuum vapor deposition and these materials are suitable for sputtering.

Next, steps of forming the functional layer 8 are explained.

In forming the functional layer 8 made of a polymer material on the glass substrate 2 on which the anode 3, the insulating layer 4 and the intermediate layer 5 are formed by coating using a spinning coating method which constitutes wet processing through the above-mentioned process, in the embodiment 1, as a polymer organic electroluminescence material, a MEH-PPV which is dissolved in toluene is used and the film thickness of the functional layer 8 is set to 120 nm. MEH-PPV is very popularly used as the polymer organic electroluminescence material and is obtainable, for example, from Nihon Siber Hegner Corp.

The polymer organic electroluminescence material per se is not limited to MEH-PPV. Currently, there have proposed polymer organic electroluminescence materials which possess various properties and light emitting colors and the functional layer 8 may be formed by suitably selecting some materials from these materials.

Here, in the embodiment 1, the functional layer 8 is formed of a single-layer film made of MEH-PPV. However, as will be explained later, the functional layer 8 may be formed of a stacked film which is formed of several material layers. For example, to enhance the re-coupling efficiency by sealing electrons injected into the inside of the MEH-PPV layer, a layer made of a material having an electron blocking function or a hole blocking function may be added. The addition of such a layer brings about the enhancement of the properties of the organic electroluminescence element 1 and is desirable.

FIG. 3 is a cross-sectional view of an example in which the functional layer 8 is constituted of a plurality of layers in the embodiment 1.

In FIG. 3, numeral 6 indicates an organic material layer having a function as an electron blocking layer, and numeral 7 indicates a light emitting layer which is made of a polymer organic electroluminescence element material. As described above, the light emitting layer 7 is made of MEH-PPV.

Hereinafter, the structure and the function of the organic electroluminescence element 1 when the functional layer 8 is formed of the plurality of layers are explained in conjunction with FIG. 3.

The organic material layer 6 is, after forming the intermediate layer 5, formed by wet processing such as a spin coating method, for example. The whole surface of the coated surface or at least a boundary portion between the anode 3 and the insulating layer 4 is covered with molybdenum oxide layer which constitutes the above-mentioned intermediate layer 5 and hence, it is possible to form the organic material layer 6 as a film having the favorable uniformity. That is, in forming the organic material layer 6, the coating surface is already covered with the uniform inorganic film by the intermediate layer 5 and hence, it is possible to form the organic material layer 6 as the film having the favorable uniformity even by wet processing.

Although the organic material layer 6 has a coating surface thereof covered with the intermediate layer 5, these layers differ in wettability and hence, there exists a possibility that the slight non-uniformity may arise in thickness of the organic material layer 6. However, the organic material layer 6 is formed as the film having an extremely small thickness as will be explained later and hence, even the film thickness of the organic material layer 6 becomes non-uniform slightly, in an actual operation of the organic electroluminescence element 1, the uniformity of the light emission is not influenced by such non-uniformity in thickness of the organic material layer 6.

In this embodiment 1, as a material of the organic material layer 6, Poly[9,9-dioctylfluorenyl-2,7-diyl]-co-1,4-benzo-{2,1′-3}-thiadiazole)]) is used. Using this material, the organic material layer 6 is formed as a thin film having a thickness of 10 nm by a spinning coating method which constitutes wet processing.

The material functions as an electron blocking layer in combination with MEH-PPV which is the material of the light emitting layer 7 and has an advantageous effect that the material can enhance the light emitting efficiency of the organic electroluminescence element 1 for preventing the electrons which are injected from the cathode 9 from passing through the anode 3.

It is desirable to lower the viscosity by lowering the concentration of the solution used of the spin coating method for forming the organic material layer 6 into a thin film having a film thickness of 10 nm. In this embodiment 1, for the formation of the organic material layer 6 having the film thickness of 10 nm, the concentration of the solution is set to 0.5%. However, this concentration indicates merely a typical value and the concentration is not limited to this value. The film thickness of the organic material layer 6 is influenced by, besides the concentration of the solution, a molecular weight of the organic material, a kind of a solvent, a rotational speed at the time of performing spin coating, spin coating atmosphere or the like. When the viscosity of the solution is high due to slightly high concentration of the solution, a large molecular weight of the organic material dissolved in the solution or the like, it is possible to form the organic material layer 6 having a certain thin thickness by increasing the rotational speed at the time of performing spin coating.

The above-mentioned solution concentration of 0.5% is a typical value which is obtained by assuming a molecular weight of a material which forms the organic material layer 6 as a value in the vicinity of 200,000 and the rotational speed which is a general spin coating condition as a value which falls within a range from 1000 to 5000 rpm. An average molecular weight of the material assumes a value which falls within a range approximately from 100,000 to 500,000 and is preferably approximately 200,000. A solution having the concentration of approximately 0.1 to 2.0% is prepared using such an organic material and, by adjusting conditions such as a rotational speed of a spin coater at the time of applying a spin coating method, it is possible to easily form the organic material layer 6 having the film thickness of 10 nm.

As has been explained heretofore, by forming the IS two-layered film which is constituted of the organic material layer 6 formed by wet processing and the light emitting layer 7 as the functional layer 8 on the intermediate layer 5 formed by dry processing, it is possible to manufacture the organic electroluminescence element 1 which exhibits the uniform distribution of thickness of the functional layer 8 which is a sum of the thickness of the organic material layer 6 and the thickness of the light emitting layer 7 in applying the functional layer 8 using wet processing.

In this manner, the functional layer 8 is applied to an upper surface of the intermediate layer 5 by wet processing. Here, in the inside of the functional layer 8, not to mention that a surface on which the light emitting layer 7 is formed is already covered with the film having the uniform wettability which constitutes the organic material layer 6 and, at the same time, the wettability of the solution which dissolves the material of the light emitting layer 7 therein is extremely close to the wettability of the film which is formed of the organic material layer 6 and hence, it is possible to form the functional layer 8 which exhibits the extreme uniformity with respect to the total thickness of the functional layer 8. By making the distribution of the thickness of the functional layer 8 uniform in this manner, the distribution of an electric field inside the functional layer 8 becomes uniform and hence, the organic electroluminescence element 1 can make the distribution of light emission brightness on a light emitting surface uniform.

The explanation is made further by returning back to FIG. 1 hereinafter.

Then, finally, the cathode 9 is formed. In the embodiment 1, the cathode 9 is formed of a stacked electrode which is constituted of a barium film and a silver film. Barium accelerates the injection of electrons from the cathode 9 and is advantageous in lowering a driving voltage of the organic electroluminescence element 1. To achieve a similar object, calcium or a compound such as lithium fluoride or the like may be used as a material of the cathode 9. Further, silver exhibits the extremely high reflectance and hence, by forming an uppermost layer of the cathode 9 using silver, it is possible to obtain an advantageous effect that light radiated to the cathode 9 side can be effectively returned toward the glass substrate 2 side thus substantially enhancing the light emitting efficiency of the organic electroluminescence element 1.

FIG. 4 and FIG. 5 are characteristic graphs in which the light emission characteristic of the organic electroluminescence element 1 according to the embodiment 1 of the present invention which has the molybdenum oxide layer as the intermediate layer 5 (see FIG. 1, hereinafter referred to as “intermediate layer element”) and the light emission characteristic of an organic electroluminescence element 11 according to a prior art which lacks an intermediate layer (see FIG. 12, hereinafter referred to as “PEDOT element”) are compared with each other.

Hereinafter, the difference in the light emission characteristic between the intermediate layer element according to the embodiment 1 of the present invention and the PEDOT element according to the prior art is explained.

In FIG. 4, the current density, that is, a value which is obtained by converting a current which flows in the organic electroluminescence element into a value per unit area is taken on an axis of abscissas, and a voltage which is applied to the organic electroluminescence element for allowing the current to flow in the organic electroluminescence element is taken on an axis of ordinates. Further, in the drawing, (a) indicates the characteristic of the PEDOT element and (b) indicates the characteristic of the intermediate layer element respectively. It is understood from FIG. 4 that irrespective of the presence or the non-presence of the intermediate layer 5, the voltages necessary for allowing the currents to flow in the organic electroluminescence element are substantially equal. The reason may be that the molybdenum oxide layer which is formed as the intermediate layer 5 is extremely thin or the difference between the first ionization potential (5.5 eV as mentioned above) of the molybdenum oxide layer and the first ionization potential (5.0 eV as mentioned above) of the anode which is made of ITO is relatively small.

Next, the relationship between a current which flows in the organic electroluminescence element and the light emission intensity which is obtained due to such inflow of the current to the organic electroluminescence element is explained in conjunction with FIG. 5. In FIG. 5, the above-mentioned current density is taken on an axis of abscissas, and the above-mentioned light emission intensity of the organic electroluminescence element, that is, the brightness is taken on an axis of ordinates. Further, in the same manner as FIG. 4, in the drawing, (a) indicates the characteristic of the PEDOT element and (b) indicates the characteristic of the intermediate layer element respectively. Both organic electroluminescence elements exhibit the linear characteristics with respect to the relationship between the current density or driving current of the organic electroluminescence element and the light emission brightness.

When an object exhibits high light emitting efficiency, this implies that a quantity of light which is obtained when the same current flows in the object is large, that is, the object is bright. FIG. 5 shows that an object having the characteristic line closer to the axis of ordinates exhibits the higher efficiency.

As can be understood from FIG. 5, the intermediate layer element (b) has the characteristic closer to the axis of ordinates compared to the PEDOT element (a) That is, the intermediate layer element (b) exhibits the higher light emitting efficiency with respect to the current. As mentioned previously, the element hiving the higher light emitting efficiency requires the smaller current value to be supplied to the element for obtaining the same light intensity. Here, as shown in FIG. 4, when the current values which flow in the PEDOT element and the intermediate layer element are equal, the voltages which are applied to both organic electroluminescence elements are substantially equal and hence, the graph in FIG. 5 implies that the electricity supplied to both organic electroluminescence elements are equal and, under such a condition, the element which includes the intermediate layer 5 exhibit the more intensified light emission compared to the element which is not provided with the intermediate layer.

When the electricity necessary for obtaining the same light emission intensity, that is, the same brightness becomes small, the heat generation of the organic electroluminescence element attributed to the light emission is decreased and the deterioration of the organic electroluminescence element attributed to the heat generation is decreased. Further, both organic electroluminescence elements consisting of the PEDOT element and the intermediate layer element are driven with the same brightness, the voltage applied to the intermediate layer element becomes lower than the voltage applied to the PEDOT element and hence, a electric field which acts on respective layers which constitute the organic electroluminescence element can be decreased whereby the diffusion of impurity ions attributed to the electric field can be decreased. In this manner, the intermediate layer element exhibits the higher light emission efficiency compared with the PEDOT element and hence, the intermediate layer element can be driven under gentler conditions thus eventually enhancing the stable operation and the reliability of the element.

Here, in the embodiment 1, the molybdenum oxide layer is used as the intermediate layer 5. This is because that the molybdenum oxide layer is sufficiently stable, can allow the efficient carrier injection, and exhibits the relatively high optical transmissivity. As a material which can obtain advantageous effects substantially equal to the advantageous effects of molybdenum oxide from a viewpoint of the material properties, it is possible to use oxide such as tungsten oxide or vanadium oxide which is transition metal oxide in the same manner as molybdenum oxide.

Further, in forming the layer made of the inorganic material which constitutes the intermediate layer 5, any one selected from a group consisting of oxide, nitride, oxinitride, composite oxide may be used and the formed layer can obtain advantageous effects substantially equal to the advantageous effects of the above-mentioned molybdenum oxide layer.

As an oxide, an oxide of chrome (Cr), tungsten (W), vanadium (V), niobium (Nb), tantalum (Ta), titanium (Ti), zirconium (Zr), hafnium (Hf), scandium (Sc), yttrium (Y), thorium (Tr), manganese (Mn), iron (Fe), ruthenium (Ru), osmium (Os), cobalt (Co), nickel (Ni), cupper (Cu), zinc (Zn), cadmium (Cd), aluminum (Al), gallium (Ga), indium (In), silicon (Si), germanium (Ge), tin (Sn), lead (Pb), antimony (Sb) or bismuth (Bi) or a rare-earth element ranging from lanthanum (La) to lutetium (Lu) can be named.

Further, as a nitride, gallium nitride (GaN), indium nitride (InN), aluminumnitride (AlN), bronnitride (BN), silicon nitride (SiN), magnesiumnitride (MgN), molybdenumnitride (MoN), calcium nitride (CaN), niobium nitride (NbN), tantalum nitride (TaN), vanadium nitride (VN), zinc nitride (ZnN), zirconium nitride (ZrN), ironnitride (FeN), cuppernitride (CuN), barium nitride (BaN), lanthanum nitride (LaN), chrome nitride (CrN), yttrium nitride (YN), lithium nitride (LiN), titanium nitride (TiN) and compound nitride of the nitrides or the like can be named.

Further, as the above-mentioned oxynitride, sialon including elements of IA, IIA, IIIB group such as barium sialon (BaSiAlON), calciumsialon (CaSiAlON), ceriumsialon (CeSiAlON), lithium sialon (LiSiAlON), magnesium sialon (MgSiAlON) scandium sialon (ScSiAlON), yttrium sialon (YSiAlON), erbium sialon (ErSiAlON), neodymium sialon (NdSiAlON) and the like, or oxynitride such as multidimension SIALON or the like can be named, and further, lanthanum silicon oxynitride (LaSiON), lanthanum europium silicon oxynitride (LaEuSi₂O₂N₃), silicon oxynitride (SiON₃) or the like can be applied.

Further, as the above-mentioned complex oxide, barium titanate (BaTiO₃), strontium titanate (SrTiO₃) and others such as calcium titanate (CaTiO₃), potassium niobate (KNbO₃), bismuthic acid iron (BiFeO₃), lithium niobate (LiNbO₃), sodium vanadate (Na₃VO₄), iron vanadate (FeVO₃), titanic acid vanadium (TiVO₃), chromic acid vanadium (CrVO₃), nickel vanadate (NiVO₃), magnesium vanadate (MgVO₃), calcium vanadate (CAVO₃), lanthanum vanadate (LaVO₃), vanadiummolybdate (VMoO₅), vanadium molybdate (V₂MoO₈), lithium vanadate (LiV₂O₅), magnesium silicate (Mg₂SiO₄), magnesium silicate (MgSiO₃), zirconium titanate (ZrTiO₄), strontium titanate (SrTiO₃), plumbum magnesate (PbMgO₃), plunbum niobate (PbNbO₃), barium boronate (BaB₂O₄), lanthanumchromate(LaCrO₃), lithiumtitanate (LiTi₂O₄), lanthanum cuprate (LaCuO₄), zinc titanate (ZnTiO₃), Calcium tungstate (CaWO₄) and the like can be named.

Here, the above-mentioned compounds merely constitute a portion of all compounds which can be used in the present invention and the above-mentioned compounds include materials which take forms of compounds which differ in valency.

The above-mentioned compounds include materials which exhibit high insulating property. This is because even the material which is referred to as an insulating material may be come conductive by decreasing a thickness thereof to approximately a value which falls within a range from 1 nm to 5 nm and can be used as a material for forming the intermediate layer 5. Further, with respect to colored compounds among the above-mentioned compounds, by setting a film thickness of the formed colored compound to several nm, it is possible to obviate problems which may arise in an actual operation thus obtaining the advantageous effects of the present invention.

Here, as mentioned above, the functional layer 8 of the organic electroluminescence element 1 is not limited to the layer which simply possesses only the light emitting function but also is formed of a layer which possesses other function such as an charge transporting function besides the light emitting function or other function, or a stacked film which is formed of a plurality of materials including the above functions.

The organic material layer 6 is not also limited to the materials used in the embodiment 1. The optimum material of the organic material layer 6 should be properly selected by taking the compatibility including the wettability with the material of the functional layer 8 into consideration.

Here, the example in which the organic electroluminescence element 1 having the above-mentioned uniform light emission intensity distribution is applied to the exposure device is explained in detail.

FIG. 6 is a constitutional view of an exposure device according to the embodiment 1 of the present invention. The structure of the exposure device is explained in detail hereinafter in conjunction with FIG. 6.

In FIG. 6, numeral 33 indicates the exposure device which is mounted on an image forming apparatus not shown in the drawing, wherein the exposure device 33 is a member which forms an electrostatic latent image on a surface of a photoconductor 28. Here, a forming process of the electrostatic latent image on a surface of a photoconductor 28 and the constitution and the manner of operation of the image forming apparatus are described in detail later.

Numeral 2 indicates the glass substrate which is already explained, and on a surface A of the glass substrate 2, the organic electroluminescence element 1 which constitutes an exposure light source is formed with the resolution of 600 dpi (dot/inch) in the direction perpendicular to the drawing (main scanning direction).

Numeral 71 indicates a lens array in which rod lenses (not shown in the drawing) made of plastic or glass are arranged in a row, wherein the lens array forms a one-to-one magnification erect image from light radiated from the organic electroluminescence element 1 which is formed on the surface A of the glass substrate 2 on a surface of the photoconductor 28 on which a latent image is formed. The positional relationship among the glass substrate 2, the lens array 71 and the photoconductor 28 is adjusted such that one focusing point of the lens array 71 rests on the surface A of the glass substrate 2 and another focusing point rests on the surface of the photoconductor 28. That is, assuming a distance from the surface A to a surface of the lens array 71 closer to the surface A as L1 and a distance between another surface of the lens array 71 and the surface of the photoconductor 28 as L2, these distances L1, L2 are set to L1=L2.

Numeral 72 indicates a relay board on which a circuit is formed on a glass epoxy substrate, for example, using electronic parts. Numeral 73a indicates a connector A and numeral 73b indicates a connector B, wherein at least connectors A 73a and connectors B 73b are mounted on the relay substrate 72. The relay substrate 72 temporarily relays image data, light quantity correction data and other control signals which are supplied to the exposure device 33 from the outside through a cable 76 such as a flexible flat cable, for example and transmits these signals to the glass substrate 2.

Direct mounting of the connectors on the surface of the glass substrate 2 is difficult in view of the reliability in a joining strength or in a versatile environment in which the exposure device 33 is arranged. Accordingly, this embodiment 1 adopts a FPC (flexible printed circuit) as a joining means which joins the connector A 73a of the relay substrate 72 and the glass substrate 2 (not shown in the drawings and described in detail later), and the joining of the glass substrate 2 and the FPC is performed using an ACF (anisotropic conductive film), for example, wherein the FPC is directly connected to ITO electrodes, for example, which are preliminarily formed on the glass substrate 2.

On the other hand, the connector B 73b is a connector which connects the exposure device 33 and the outside. In general, it is often the case that such connection using the ACF or the like has a problem in a joining strength. However, by providing the connector B 73b which allows a user to connect the exposure device 33 to the relay substrate 72, it is possible to ensure a sufficient strength to the interface to which the user accesses directly.

Numeral 74a indicates a casing A which is formed by bending a metal plate, for example. An L-shaped portion 75 is formed on a side of the casing A 74a which faces the photoconductor 28 in an opposed manner, and the glass substrate 2 and lens array 71 are arranged along the L-shaped portion 75. By adopting the structure in which a photoconductor 28-side end surface of the casing A 74a and an end surface of the lens array 71 are aligned with each other on the same plane and one end portion of the glass substrate 2 is supported on the casing A 74a, forming accuracy of the L-shaped portion 75 can be ensured and hence, the positional relationship between the glass substrate 2 and the lens array 71 can be obtained with high accuracy. In this manner, the casing A 74a is required to have size accuracy and hence, it is desirable to form the casing A using metal. Further, by forming the casing A 74a using metal, it is possible to suppress the influence of noises to the control circuit which is formed on the glass substrate 2 and electronic parts such as IC chips which are mounted on the glass substrate 2 by surface mounting.

Numeral 74b indicates a casing B which is formed by molding using a resin. A cutout portion (not shown in the drawings) is formed in the casing B 74b in the vicinity of the connector B 73b of the casing B 74b, and a user can get access to the connector B 73b through the cutout portion. Through a cable 76 which is connected to the connector B 73b, the control signals such as the image data, the light quantity correction data, the clock signals and the line synchronizing signals and the like, the drive power source of the control circuit, and the drive power source of the organic electroluminescence elements which constitute the light emitting elements are supplied to the exposure device 33 from the outside of the exposure device 33.

FIG. 7(a) is a top plan view of the glass substrate 2 according to the exposure device 33 of the embodiment 1, and FIG. 7(b) is an enlarged view of an essential part. Hereinafter, the constitution of the glass substrate 2 of the embodiment 1 is explained in detail in conjunction with FIG. 7 together with FIG. 6.

In FIG. 7, the glass substrate 2 is a rectangular substrate having a thickness of approximately 0.7 mm and having at least long side and short side, wherein a plurality of organic electroluminescence elements 1 is formed in a row along the long-side direction (main scanning direction). In the embodiment 1, the organic electroluminescence elements 1 which are necessary for the exposure of at least A4 size (210 mm) are arranged along the long-side direction of the glass substrate 2, and the long-side direction size of the glass substrate 2 is set to 250 mm including an arrangement space for a drive control part 78 described later. Further, although the explanation is made with respect to a case in which the glass substrate 2 has a rectangular shape for the sake of brevity in this embodiment 1, the glass substrate 2 may be modified by cutting a portion thereof for facilitating the positioning of the glass substrate 2 at the time of mounting the glass substrate 2 in the casing A 74a.

Numeral 78 indicates the drive control part which receives control signals (signals for driving the organic electroluminescence elements 1) which are supplied from the outside of the glass substrate 2 and controls driving of the organic electroluminescence elements 1 based on the control signals. As described later, the drive control part 78 includes an interface means which receives the control signals from the outside of the glass substrate 2 and an IC chip (a source driver 81) which controls the driving of the organic electroluminescence elements 1 based on the control signals received via the interface means.

Numeral 80 indicates an FPC (flexible printed circuit) which constitutes the interface means for connecting the connector A 73a of the relay substrate 72 and the glass substrate 2, wherein the FPC 80 is directly connected to a circuit pattern not shown in the drawing which is mounted on the glass substrate 2 without using connectors or the like. As explained previously, the control signals such as the image data, the light quantity correction data, the clock signals, the line synchronizing signals and the like which are supplied to the exposure device 33 from the outside, the drive power source of the control circuit, and the drive power source of the organic electroluminescence elements 1 are supplied to the glass substrate 2 through the FPC 80 after temporarily passing through the relay substrate 72 shown in FIG. 6.

In the embodiment 1, 5120 pieces of organic electroluminescence elements 1 as a light source of the exposure device 33 are formed in a row with the resolution of 600 dpi in the main scanning direction, wherein the respective individual organic electroluminescence elements 1 are subjected to a turn ON/OFF control independently by TFT circuits described later.

Numeral 81 indicates the source driver which is supplied as an IC chip which controls the driving of the organic electroluminescence elements 1, and the source driver 81 is mounted on the glass substrate 2 by flip-chip mounting. By taking into consideration that the source driver 81 is mounted on the surface of the glass substrate 2, a bear chip product is adopted as the source driver 81. To the source driver 81, the power source, the control relevant signals such as clock signals, line synchronizing signals and the like, and the light quantity correction data (for example, multiple-value data of 8 bits) are supplied from the outside of the exposure device 33 through the FPC 80. The source driver 81 is a drive parameter setting means with respect to the organic electroluminescence elements 1. To be more specific, the source driver 81 serves to set drive current values of the individual organic electroluminescence elements 1 based on the light quantity correction data received through the FPC 80.

On the glass substrate 2, a joining portion of the FPC 80 and the source driver 81 are connected with each other through a circuit pattern (not shown in the drawing) made of ITO which is formed on the surface of the glass substrate 2 using metal. To the source driver 81 which constitutes the drive parameter setting means, the control signals such as the light quantity correction data, the clock signals, the line synchronizing signals or the like are inputted through the FPC 80. In this manner, the FPC 80 which constitutes the interface means and the source driver 81 which constitutes the drive parameter setting means form the drive control part 78.

Numeral 82 indicates a TFT (Thin Film Transistor) circuit formed on the glass substrate 2. The TFT circuit 82 includes gate controllers such as a shift register and a data latch part which control timing for turning ON and OFF the organic electroluminescence elements 1 and a drive circuit which supplies a drive current to individual organic electroluminescence element 1 (hereinafter referred to as a pixel circuit). The pixel circuit is provided to each organic electroluminescence element 1 in one-to-one relationship and is arranged in parallel to the row of light emitting elements which the organic electroluminescence elements 1 form. By the source driver 81 which constitutes the drive parameter setting means, a drive current value for driving the individual organic electroluminescence element 1 is set to the pixel circuit.

To the TFT circuit 82, the power source, the control signals such as the clock signals, the line synchronizing signals and the like and the image data (binary data of 1 bit) are supplied from the outside of the exposure device 33 through the FPC 80, and the TFT circuits 82 controls the turn on/off timing of individual organic electroluminescence elements 1 based on these power source and signals.

Numeral 84 indicates sealing glass. When the organic electroluminescence element 1 is influenced by moisture, the light emitting region is shrunken or minute non-light emitting portion (a dark spot) in the inside of the light emitting region is expanded along with a lapse of time thus remarkably deteriorating the light emitting characteristics. Accordingly, it is necessary to seal the exposure device to interrupt the influence of the moisture to the exposure device. In the embodiment 1, a matted sealing method which adheres the sealing glass 84 to the glass substrate 2 by way of an adhesive agent is adopted. However, to absorb the moisture in the sealing region, a descant not shown in the drawing may be arranged between the sealing glass 84 and the glass substrate 2. The sealing region of several millimeter to several centimeter is necessary in the sub scanning direction from the row of light emitting elements which is constituted by the organic electroluminescence elements 1 in general, wherein 2000 μm is ensured as a sealing margin in the embodiment 1.

Numeral 77 indicates a light quantity sensor unit in which a plurality of light quantity sensors which are made of amorphous silicon or the like is arranged in the main scanning direction along the glass substrate 2. A light emitting quantity of the individual organic electroluminescence element 1 is measured by the light quantity sensor unit 77. An output of the light quantity sensor unit 77 is temporarily fetched to the TFT circuit 82 through a line not shown in the drawing, is amplified by a signal processing means not shown in the drawing, is subjected to signal processing such as analog-digital conversion and, thereafter, is outputted to the outside of the exposure device 33 through the FPC 80, the relay substrate 72 (see FIG. 6) and a cable 76 (see FIG. 6).

The signal is received and processed by a controller (not shown in the drawing) which is incorporated in the image forming apparatus, and the light quantity correction data (for example, 8 bits=256 steps) is generated. However, what is measured by the light quantity sensor unit 77 is the total emitted light quantity of the individual organic electroluminescence elements 1 and is not the distribution of the light emission brightness of the light emitting region. Accordingly, although the total emitted light quantity of the organic electroluminescence elements 1 may be restored by the correction based on the light quantity correction data, it is difficult to restore the distribution of the light emission brightness in the light emitting region which is changed by deterioration with a lapse of time, for example.

In the embodiment 1, as mentioned previously, a thickness of a functional layer 8 (see FIG. 1 or FIG. 3) is made uniform and the distribution of the light emitting intensity of the organic electroluminescence elements 1 is made uniform and hence, the deterioration of the organic electroluminescence element 1 occurs uniformly whereby even when such deterioration occurs, the distribution of the light emission brightness within the light emitting region is not changed.

Accordingly, the exposure device 33 which uses the organic electroluminescence elements 1 of this embodiment 1 can acquire an extremely remarkable advantageous effect that, as mentioned above, by merely measuring the emitted light quantity of the individual organic electroluminescence elements 1 based on the light quantity sensor unit 77 and by re-setting the drive currents which drive the organic electroluminescence elements 1 based on the measured emitted light quantity, it is possible to surely restore both of the total emitted light quantity of the organic electroluminescence elements 1 and the distribution of the light emission brightness in the light emitting region.

Here, in the embodiment 1, the FPCO 80 which is the interface means constituting the drive control part 78 and the source driver 81 which is the drive parameter setting means are positioned on an extension (EL_dir) of the row of light emitting elements which the organic electroluminescence elements 1 form.

Due to such an arrangement, the drive control part 78 is arranged at a position where the drive control part 78 is not overlapped to the row of the light emitting elements at arbitrary positions in the long-side direction (main scanning direction) of the glass substrate 2. Simultaneously, in the above-mentioned constitution, at an arbitrary position along the long-side direction (main scanning direction) of the glass substrate 2, the drive control part 78 is arranged at the position where the drive control part 78 is not overlapped to the TFT circuit 82 (including the pixel circuit) which is formed in parallel to the row of the light emitting elements. Due to such an arrangement, it is possible to reduce a size of the glass substrate 2.

FIG. 8 is an explanatory view showing a state in which the photoconductor 28 is exposed by the exposure device 33 to which the organic electroluminescence element 1 of the embodiment 1 of the present invention is applied.

In FIG. 8, numeral 20 indicates a propagation path of light which is radiated from the organic electroluminescence element 1. The organic electroluminescence element 1 is formed on a surface A of the glass substrate 2 (see FIG. 6) and a lower surface of the glass substrate 2 forms a light take out surface.

Hereinafter, a latent image forming process by the exposure device 33 of the embodiment 1 is explained in detail in conjunction with FIG. 8.

Here, in FIG. 8, for the sake of brevity, only parts which are necessary for the explanation is extracted and described. Further, the explanation is made assuming that the glass substrate 2, a lens array 71 and the like are supported on a casing 74a shown in FIG. 6, and the positional relationship between the photoconductor 28 and the lens array 71 is properly maintained.

Further, in the embodiment 1, as an optical system which forms an erect equal magnification image on the photoconductor 28, the lens array 71 which has been explained heretofore is used. However, this light guide system may adopt any system provided that the system can properly focus a radiation light from the organic electroluminescence element 1 on the photoconductor 28 to form an image and, for example, a microlens array or a planar optical system may be used. Further, on the glass substrate 2 having a thickness which is equal to or less than a maximum diameter of the organic electroluminescence element 1 (the maximum diameter being approximately 40 μm since 600 dpi is assumed in the embodiment 1), the organic electroluminescence element 1 is formed thus constituting a so-called lens-free contact exposure system.

The organic electroluminescence element 1 shown in FIG. 8 is one of 5120 pieces of organic electroluminescence elements 1 formed on the glass substrate 2 with the resolution of 600 dpi. In actually performing the exposure, a large number of these organic electroluminescence elements 1 are controlled in an associated manner as have been already explained in conjunction with FIG. 7 thus forming a two-dimensional printed image.

A so-called electrophotographic process in which a latent image is formed on the photoconductor 28 and a toner image which is visualized by developing the latent image, and the toner is transferred to a paper sheet and, subsequently, the toner image is fixed by heating is explained later. Here, the explanation is made with respect to steps in which the light from the organic electroluminescence element 1 is focused on to the photoconductor 28 thus forming the electrostatic distribution referred to as the latent image and, thereafter, the toner is adhered to the latent image.

First of all, a surface of the photoconductor 28 is charged or electrified using a charging unit such as a scotron charger, a roller charger or the like not shown in the drawing. Next, the radiation light from the organic electroluminescence element 1 is propagated using the lens array 71 and, thereafter, is focused on the surface of the photoconductor 28. Here, since the lens array 71 is formed of erect one-to-one magnification lenses, the radiation light from the organic electroluminescence element 1 passes through the propagation path 20 and is focused on the photoconductor 28 while maintaining the light emitting surface shape and the light emitting intensity distribution. That is, the light emission intensity distribution of the light emission surface of the organic electroluminescence element 1 is directly reflected on the photoconductor 28.

A potential is released from only regions which receive light on the photoconductor 28, and an electrostatic image which cannot be viewable with naked eyes, that is, a latent image can be formed. This is because that the photoconductor 28 is formed of a material having light conductivity. Due to the radiation of light to the portions, the conductivity of only the portions is elevated and hence, a charge of portions which receive light passes conductive portions which are formed on a back surface of the photoconductor 28 thus releasing the charge to a ground. Here, a degree of discharging of the charge on the surface of the photoconductor 28 depends on the intensity of light which is radiated during a fixed period, and portions which receive stronger light exhibit the surface potential closer to the potential of the ground. Accordingly, the latent image exhibits a shape which reflects the intensity distribution of the radiated light, that is, the light emission intensity distribution of the organic electroluminescence element 1.

After the formation of the latent image, the adhesion of toner is applied to the surface of the photoconductor 28 by a developing unit also not shown in the drawing. The toner is charged with a preset predetermined potential, and by applying a predetermined bias potential to the developing unit not shown in the drawing, the predetermined potential generates an electrostatic interaction with a surface potential of the photoconductor 28, and the toner is adhered to the portions of the photoconductor 28 where the latent image is formed in response to a Coulomb force based on the surface potential. Also in this case, a degree of adhesion of the toner on the photoconductor 28 depends on a state of the latent image, that is, the light emission intensity distribution of the organic electroluminescence element 1.

In this manner, the light emission intensity distribution of the organic electroluminescence element 1 which constitutes the light source of the exposure device 33 eventually influences an adhesion state of the toner on the photoconductor 28 and this toner adhesion state is directly reflected on a printing result.

Here, since the state of the latent image on the photoconductor 28 directly reflects the light emission state of the organic electroluminescence element 1, the maintenance of the stable light emission state of the organic electroluminescence element 1 for a long period becomes a prerequisite for maintaining the high image quality.

The explanation is continued hereinafter by also in conjunction with FIG. 1.

The organic electroluminescence element 1 explained in conjunction with the embodiment 1 includes the intermediate layer 5, wherein since the light emission efficiency is enhanced, the heat generation is extremely small thus allowing the organic electroluminescence element 1 to perform the stable and highly reliable operation for a long period. By making the exposure device adopt such an organic electroluminescence element 1 as the light source, it is possible to provide the highly reliable exposure device which can perform the stable operation for a long period.

In the organic electroluminescence element 1 which forms the functional layer 5 made of a film by wet processing in this manner, by arranging the functional layer 8 which includes at least a light emitting layer and the intermediate layer 5 between the pair of electrodes consisting of the anode 3 and the cathode 9, and by setting the surface resistivity of the intermediate layer 5 to a value which falls within the predetermined range, the organic electroluminescence element 1 can be manufactured at a low cost, can eliminate an electric crosstalk, and can exhibit the high light emission efficiency whereby it is possible to acquire the excellent organic electroluminescence element 1 which exhibits the low heat generation thus lowering the deterioration attributed to the heat generation and can perform the stable operation over the long period. Further, by using such an organic electroluminescence element 1 in the exposure device 33, the latent image can be formed on the photoconductor 28 in a stable manner thus realizing the exposure device 38 which can generate a clear and accurate printing output.

Further, as has been explained in conjunction with FIG. 3, the organic material layer 6 and the light emitting layer 7 which constitute the functional layer 8 can be formed using simple wet processing and hence, a manufacturing facility cost can be lowered and, at the same time, time necessary for manufacturing the organic electroluminescence element 1 as a film can be shortened and hence, a manufacturing cost of the organic electroluminescence element 1 is lowered whereby it is possible to provide the exposure device 33 at a low cost,

FIG. 9 is a constitutional view of the image forming apparatus on which the exposure device 33 to which the organic electroluminescence element 1 of the embodiment 1 of the present invention is applied is mounted.

In FIG. 9, the image forming apparatus 21 arranges, in the inside of the device, developing stations of four colors consisting of a yellow developing station 22Y, a magenta developing station 22M, a cyan developing station 22C and a black developing station 22K in a step-like manner in the vertical direction. A paper feeding tray 24 which incorporates recording papers 23 is arranged above the developing stations 22Y to 22K and, at the same time, at positions corresponding to the respective developing stations 22Y to 22K, recording paper conveying passages 25 which become conveying passages for recording papers 23 which are supplied from the paper feeding tray 24 are arranged in the downward vertical direction.

The developing stations 22Y to 22K form toner images of yellow, magenta, cyan and black in order from an upstream side of the recording paper conveying passage 25, wherein the yellow developing station 22Y includes a photoconductor 28Y, the magenta developing station 22M includes a photoconductor 28M, the cyan developing station 22C includes a photoconductor 28C, and the black developing station 22K includes a photoconductor 28K, wherein each developing station 22Y, 22M, 22C or 22K includes a series of members for realizing a developing process in an electrophotographic method such as a developing sleeve, a charger and the like not shown in the drawing.

Further, exposure devices 33Y, 33M, 33C, 33K for forming the electrostatic latent image by exposing surfaces of the photoconductors 28Y to 28K are arranged below the respective developing stations 22Y to 22K.

Here, although the developing stations 22Y to 22K have colors of developers which are filled therein made different from each other, the developing stations 22Y to 22K have the same constitution in spite of the developed colors. To facilitate the explanation made hereinafter, unless otherwise particularly necessary, the explanation is made without specifying the particular color such as the developing station 22, the photoconductor 28 and the exposure device 33.

FIG. 10 is a constitutional view showing a periphery of the developing station 22 in the image forming apparatus 21 of the embodiment 1 of the present invention. In FIG. 10, a developer 26 which is a mixture of a carrier and a toner is filled in the inside of the developing station 22. Numerals 27a, 27b are agitation puddles which agitate the developer 26, wherein due to the rotation of the agitation paddles 27a, 27b, the toner in the inside of the developer 26 is charged with a predetermined potential due to a friction with the carrier and, at the same time, the toner is circulated in the inside of the developing station 22 thus providing the sufficient agitation and mixing of the toner and the carrier. The photoconductor 28 is rotated in the direction D3 by a drive source not shown in the drawing. Numeral 29 indicates a charger which charges a surface of the photoconductor 28 with a predetermined potential. Numeral 30 indicates a developing sleeve and numeral 31 indicates a layer thinning blade. The developing sleeve 30 includes a magnet roll 32 on which a plurality of magnetic poles are formed therein. A layer thickness of the developer 26 which is supplied to the surface of the developing sleeve 30 is restricted by the layer thinning blade 31 and, at the same time, the developing sleeve 30 is rotated in the direction D4 by a drive source not shown in the drawing. Due to this rotation and an action of the magnetic poles of the magnet roll 32, the developer 26 is supplied to the surface of the developing sleeve 30 thus developing an electrostatic latent image which is formed on the photoconductor 28 by the exposure device described later and, at the same time, the developer 26 which is not transferred to the photoconductor 28 is recovered in the inside of the developing station 22.

Numeral 33 indicates the exposure device which is explained already. In the image forming apparatus 21 to which the exposure device 33 of the embodiment 1 is applied, as described previously, the organic electroluminescence element 1 of the embodiment 1 is configured such that each organic electroluminescence element 1 exhibits the extremely uniform light emission intensity distribution and, at the same time, exhibits the high and stable light emission property over a long period and hence, the exposure device 33 of the embodiment 1 can obtain the stable electrostatic latent image having a predetermined shape for a long period. Accordingly, the image forming apparatus 21 which mounts the exposure device 33 thereon can always form the high-quality image. Here, in the exposure device 33 of the embodiment 1, the organic electroluminescence elements 1 are arranged in a straight line with the resolution of 600 dpi (dot/inch), wherein by selectively turning on and off the organic electroluminescence elements 1 with respect to the photoconductor 28 which is charged with a predetermined potential by the charger 29 in response to image data, it is possible to form an electrostatic latent image of an A4 size at maximum. Only the toner out of a developer 26 which is supplied to a surface of a developing sleeve 30 is adhered to the electrostatic latent image portions thus visualizing the static latent image. Since the steps for visualizing the electrostatic latent image portions is already explained in detail in conjunction with FIG. 8, the explanation is omitted here.

At a position which faces the recording paper conveying passage 25 with respect to the photoconductor 28, a transfer roller 36 is provided, and the transfer roller 36 is rotated in the direction D5 by a drive source not shown in the drawing. A predetermined transfer bias is applied to the transfer roller 36 so as to transfer the toner image formed on the photoconductor 28 to the recording paper which is conveyed along the recording paper conveying passage 25.

The explanation is continued by returning to FIG. 9.

As has been explained heretofore, the image forming apparatus 21 of this embodiment 1 is a tandem-type color image forming apparatus which arranges the plurality of developing stations 22Y to 22K in the vertical direction in a step-like manner. The image forming apparatus 21 aims at a size which is equal to a size of a color ink jet printer of the equivalent class. In each developing station 22Y, 22M, 22C, 22K, the plurality of units are arranged and hence, to achieve the miniaturization of the image forming apparatus 21, along with the miniaturization of the developing stations 22Y to 22K, it is necessary to reduce sizes of members which contribute to an image forming process and are arranged in a periphery of the developing stations 22Y to 22K so as to make an arrangement pitch of the developing stations 22Y to 22K as small as possible.

To take the easy-to-use property for the user, particularly the accessibility of the user to the recording paper 23 at the time of feeding the paper or discharging the paper when the image forming apparatus 21 is mounted on a desk top in an office or the like into consideration, it is desirable Lo set a height of image forming apparatus 21 from a bottom surface to a paper feed port 65 to 250 mm or less. To realize such a constitution, it is necessary to suppress a height of the whole developing stations 22Y to 22K to approximately 100 mm in the whole constitution of the image forming apparatus 21.

However, an existing LED head has a thickness of approximately 15 mm, for example and hence, when such an LED head is arranged between the developing stations 22Y to 22K, it is difficult to achieve a targeted constitution. According to a result of the review of inventors and the like of the present invention, by setting a thickness of the exposure device 33 to 7 mm or less, even when the exposure device 33Y, 33M, 33C, 33K is arranged in a gap between the developing stations 22Y to 22K, it is possible to suppress the height of the whole developing station to 10 mm or less.

Numeral 37 indicates toner bottles in which toners of yellow, magenta, cyan and black are stored. Toner conveying pipes not shown in the drawing are arranged between the toner bottles 37 and the respective developing stations 22Y to 22K so as to supply the toners to the respective developing stations 22Y to 22K.

Numeral 38 indicates a paper feed roller. The paper feed roller 38 is rotated in the direction D1 by controlling an electromagnetic clutch not shown in the drawing thus feeding the recording paper 23 loaded in the paper feeding tray 24 to the recording paper conveying passage 25.

To the recording paper conveying passage 25 which is positioned between the paper feed roller 38 and the transfer portion of the yellow developing station 22Y which is arranged at the most upstream side, a pair of a resist roller 39 and a pinch roller 40 is provided as a nip conveying means on an inlet side. The pair of the resist roller 39 and the pinch roller 40 temporarily stops the recording paper 23 which is conveyed from the paper feed roller 38 and conveys the recording paper 23 in the direction toward the yellow developing station 22Y at a predetermined timing. Due to this temporarily stop, a leading end of the recording paper 23 is restricted to be in parallel with the axial direction of the pair of the resist roller 39 and the pinch roller 40 thus preventing skewing of the recording paper 23.

Numeral 41 indicates a recording paper passing detection sensor. The recording paper passing detection sensor 41 is formed of a reflective sensor (photo reflector) and detects the leading end and a trading end of the recording paper 23 based on the presence or the non-presence of a reflection light.

When the rotation of the resist roller 39 is started (the rotation turning ON/OFF operation being performed by controlling the power transmission using an electromagnetic clutch not shown in the drawing), the recording paper 23 is conveyed in the direction toward the yellow developing station 22Y along the recording paper conveying passage 25. Here, using the timing that the rotation of the resist roller 39 is started, the writing timings of electrostatic latent images by the exposure devices 33Y to 33K which are arranged in the vicinity of the respective developing stations 22Y to 22K are independently controlled.

At a portion of the recording paper conveying passage 25 which is positioned further downstream of the most-downstream black developing station 22K, a fixing unit 43 is provided as a nip conveying means on an outlet side. The fixing unit 43 is constituted of a heating roller 44 and a pressing roller 45. The heating roller 44 is a roller having the multi-layered structure which is constituted of a heat generating belt, a rubber roller and a core (none of them shown in the drawing) in order from the surface of the heating roller 44. Here, the heat generating belt is formed of a belt having the three-layered structure which is constituted of a peel-off layer, a silicon rubber layer and a base material layer (none of them shown in the drawing) from a side close to the surface of the belt. The peel-off layer is formed of a fluororesin film having a thickness of approximately 20 to 30 μm thus imparting the peel-off property to the heating roller 44. The silicon rubber layer is formed of a silicon rubber film having a thickness of approximately 170 μm and gives proper resiliency to the pressing roller 45. The base material layer is made of a magnetic material which is alloy of iron, nickel, chromium and the like.

Numeral 26 indicates a back core in which an excitation coil is encased. In the inside of the back core 46, the excitation coil which is formed of a bundle of a predetermined number of copper-made wires (not shown in the drawing) which have surfaces thereof insulated extends in the rotary axis direction of the heating roller 44, and is wrapped around both end portions of the heating roller 44 in the circumferential direction of the heating roller 44. By applying an AC current of approximately 30 kHz to the excitation coil from an excitation circuit (not shown in the drawing) which constitutes a semi-resonance type inverter, a magnetic flux is generated in a magnetic path which is constituted of the back core 46 and the base material layer of the heating roller 44. Due to this magnetic flux, an eddy current is generated in the base material layer of the heat generating belt of the heating roller 44 and hence, the base material layer is heated. The heat generated in the base material layer is transmitted to the peel-off layer by way of the silicon rubber layer thus heating the surface of the heating roller 44.

Numeral 47 indicates a temperature sensor for detecting a temperature of the heating roller 44. The temperature sensor 47 is formed of a ceramic semiconductor which is obtained by high-temperature sintering using metal oxide as a main material, wherein the temperature sensor 47 can measure a temperature of an object which is in contact with the temperature sensor 47 by making use of a change of a load resistance in response to temperature. An output of the temperature sensor 47 is inputted to a control device not shown in the drawing, and the control device controls an electric power which is outputted to the excitation coil in the inside of the back core 46 based on the output of the temperature sensor 47 such that a surface temperature of the heating roller 44 is set to approximately 170° C.

When the recording paper 23 on which the toner image is formed passes a nip portion which is formed by the heating roller 44 to which the temperature control is applied and the pressing roller 45, the toner image formed on the recording paper 23 is heated and pressurized by the heating roller 44 and the pressing roller 45 so that the toner image is fixed to the recording paper 23.

Numeral 48 indicates a recording-paper trading-end detection sensor. The recording-paper trading-end detection sensor 48 monitors a discharge state of the recording paper 23. Numeral 52 indicates a toner image detection sensor. The toner image detection sensor 52 is a reflective sensor unit which uses a plurality of light emitting elements which differ in light emitting spectrum (all visual lights) and a single light receiving element, wherein the toner image detection sensor 52 detects the image density by making use of the difference in absorption spectrum in response to color of image between a background and an image forming portion of the recording paper 23. Further, the toner image detection sensor 52 can detect not only the image density but also the image forming position and hence, in the image forming apparatus 21 of the embodiment 1, the toner image detection sensors 52 are provided at two positions spaced apart in the widthwise direction of the image forming apparatus 21, and the image forming timing is controlled based on detected positions of an image position displacement quantity detection pattern formed on the recording paper 23.

Numeral 53 indicates a recording paper conveying drum. The recording paper conveying drum 53 is a metal-made roller which has a surface thereof covered with rubber having a thickness of approximately 200 μm, and the recording paper 23 after fixing is conveyed in the direction D2 along the recording paper conveying drum 53. Here, the recording paper 23 is cooled by the recording paper conveying drum 53 and, at the same time, is bent in the direction opposite to the image forming surface and is conveyed. Due to such an operation, it is possible to largely reduce curling which may occur when an image of high concentration is formed on a whole surface of the recording paper 23. Thereafter, the recording paper 23 is conveyed in the direction D6 by a kick-out roller 55 and is discharged to a paper discharge tray 59.

Numeral 54 indicates a face-down paper discharging portion. The face-down paper discharging portion 54 is configured to be rotatable about a support member 56, wherein by bringing the face-down paper discharging portion 54 into an open state, the recording paper 23 is discharged in the direction D7. On aback surface of the face-down paper discharging portion 54, a rib 57 is formed along the conveying passage so as to guide the conveyance of the recording paper 23 together with the recording paper conveying drum 53 in a closed state.

Numeral 58 indicates a drive source and a stepping motor is adopted as the driving source 58 in the embodiment 1. The drive source 58 drives the paper feed roller 38, the resist roller 39, the pinch roller 40, peripheral portions of respective developing stations 22Y to 22K including the photoconductors (28Y to 28K) and the transfer rollers (36Y to 36K), the fixing unit 43, the recording paper conveying drum 53 and the kick-out roller 55.

Numeral 61 indicates a controller. The controller 61 receives image data from a computer or the like not shown in the drawing via an external network and develops and forms image data which can be printed.

Numeral 62 indicates an engine control part. The engine control part 62 controls hardware and a mechanism of the image forming apparatus 21, wherein the engine control part 62 forms a color image on a recording paper 23 based on the image data transferred from the controller 61 and, at the same time, performs an overall control of the image forming apparatus 21.

Numeral 63 indicates a power source part. The power source part 63 performs the power supply of the predetermined voltage to the exposure devices 33Y to 33K, the drive source 58, the controller 61 and the engine control part 62 and, at the same time, performs the power supply to the heating roller 44 of the fixing unit 43. Further, this power source part 63 also includes a so-called high-voltage power source system such as a charger which charges a surface of the photoconductor 28, a developing bias system which applies a developing bias to the developing sleeves (see numeral 30 in FIG. 10) and a transfer bias system which applies a transfer bias to the transfer rollers 36.

Further, the power source part 63 includes a power source monitoring part 64 so as to monitor a power source voltage which is supplied to at least engine control part 62. A monitor signal is detected by the engine control part 62, wherein the lowering of the power source voltage which is generated when a power source switch is turned off or the service interruption occurs is detected.

In the above-mentioned explanation, the explanation has been made with respect to the case in which the present invention is applied to the color image forming apparatus. However, the present invention is applicable to an image forming apparatus of monochroic color such as black, for example. Further, when the present invention is applied to the color image forming apparatus, the developing colors are not limited to four colors consisting of yellow, magenta, cyan and black.

(Embodiment 2)

FIG. 11 is a cross-sectional view of an organic electroluminescence element of the embodiment 2 of the present invention. Although the structure of the organic electroluminescence element 1 of the embodiment 2 is explained in conjunction with FIG. 11 hereinafter, since there is no difference in the constitution and the manner of operation between this embodiment 2 and the embodiment 1 with respect to the exposure device to which the organic electroluminescence element 1 is applied and the image forming apparatus which mounts the exposure device thereon, the explanation is omitted.

Although this embodiment 2 differs from the embodiment 1 with respect to a point that the organic electroluminescence element 1 in the embodiment 2 does not include the insulation layer 4 which restricts the light emitting surface (see FIG. 1), there is no substantial difference between this embodiment 2 and the embodiment 1 with respect to other constitutions.

In FIG. 11, numeral 1 indicates the organic electroluminescence element, while numeral 2 indicates, for example, a glass substrate having transmissivity which supports the organic electroluminescence element 1 thereon. In this embodiment 2, on the glass substrate 2, an anode 3 which is made of a light transmitting material such as ITO or the like, for example, is formed as one of a pair of electrodes. On the whole surface of the anode 3, a molybdenum oxide layer which constitutes an intermediate layer 5 is formed using wet processing. Subsequently, a functional layer 8 including a light emitting layer which is made of a polymer material is formed by wet processing. Finally, a cathode 9 is formed by a vacuum vapor deposition method as another of the pair of electrodes.

In this manner, the organic electroluminescence element 1 of the embodiment 2 includes the pair of electrodes which is constituted of the anode 3 and the cathode 9, and the functional layer 8 having at least the light emitting layer and the intermediate layer 5 which are arranged between the pair of electrodes, wherein the surface resistivity of the intermediate layer 5 is set to a value more than 10⁶Ω/□ and less than 10¹²Ω/□.

In this manner, with the simple structure which eliminates the insulation layer 4 (see FIG. 1), an advantageous effect attributed to the presence of the above-mentioned intermediate layer 5 having the surface resistivity which the embodiment 2 can obtain is exactly equal to the corresponding advantageous effect explained in detail in conjunction with the embodiment 1. That is, with the provision of the intermediate layer 5, the light emission efficiency of the organic electroluminescerce element 1 is enhanced and hence, it is possible to drive the organic electroluminescence element with a lower voltage whereby a cost for driving the organic electroluminescence element can be decreased. Further, it is possible to suppress an electric crosstalk between the neighboring organic electroluminescence elements. Further, the electricity supplied to the organic electroluminescence element can be decreased and hence, the heat generation is decreased whereby it is possible to prolong a lifetime of the organic electroluminescence element.

Further, also in this embodiment 2, in the same manner as the embodiment 1, the functional layer 8 may have the multi-layered structure which includes an electron blocking layer or the like besides a light emitting layer 6 (see FIG. 3).

According to the organic electroluminescence element of the present invention, a cost for driving the organic electroluminescence element is low, there is no crosstalk between the neighboring pixels, the lifetime of the organic electroluminescence element can be prolonged attributed to the high light emitting efficiency, and the light emission intensity distribution in the inside of a light emission surface is uniform and hence, the organic electroluminescence element effectively used in versatile applications including, not to mention the exposure device, a flat panel display or a display element, other light sources and the like. Further, the exposure device to which the organic electroluminescence element of the present invention is applied can form the stable latent image for a long period and hence, the exposure device is applicable to an electrophotographic device such as a printer or a copying machine and a photo printer which performs the direct exposure of a printing paper based on image data.

This application is based upon and claims the benefit of priority of Japanese Patent Application No. 2005-263406 filed on Sep. 12, 2005, the content of which is incorporated herein by references in its entirety.

What is claimed is:

1. An organic electroluminescence element, comprising;
a pair of electrodes; and
a functional layer having at least a light emitting layer and an intermediate layer which are arranged between the pair of electrodes;
wherein the surface resistivity of the intermediate layer is set to a value equal to or more than 10⁶Ω/□ and equal to or less than 10¹²Ω/□.

2. The organic electroluminescence element according to claim 1, wherein a thickness of the intermediate layer is set to a value equal to or more than 1 nm and equal to or less than 50 nm.

3. The organic electroluminescence element according to claim 1, wherein assuming a first ionization potential of the intermediate layer as IP₁eV and a first ionization potential of one of the electrodes as IP₂eV, the intermediate layer is configured to satisfy the relationship IP₂−0.5 eV≦IP₁≦IP₂+0.5 eV.

4. The organic electroluminescence element according to claim 1, wherein the intermediate layer is formed by dry processing.

5. The organic electroluminescence element according to claim 1, wherein the intermediate layer is made of any one selected from a group consisting of oxide, nitride, oxynitride and composite oxide.

6. The organic electroluminescence element according to claim 5, wherein the intermediate layer is made of oxide of transition metal.

7. The organic electroluminescence element according to claim 6, wherein the oxide of transition metal is any one selected from a group consisting of molybdenum oxide, tungsten oxide and vanadium oxide.

8. The organic electroluminescence element according to claim 1, wherein the functional layer is made of a polymer material by wet processing.

9. The exposure device which is configured such that the organic electroluminescence elements described in claim 1 are arranged in a row and turning on/off of the individual organic electroluminescence elements are controllable independently from each other.

10. The image forming apparatus comprising at least:
the exposure device described in claim 9;
a photoconductor on which an electrostatic latent image is formed by the exposure device; and
a developing means which visualizes the electrostatic latent image which is formed on the photoconductor.
